(19) United States
(12) Patent Application Publication
(10) Pub. No.: US 2012/0094235 A1
(43) Pub. Date: Apr. 19, 2012

(54) ACTINIC-RAY- OR RADIATION-SENSITIVE RESIN COMPOSITION AND METHOD OF FORMING PATTERN USING THE COMPOSITION

(75) Inventors: Toru Tsuchihashi, Shizuoka-ken (JP); Hideaki Tsubaki, Shizuoka-ken (JP); Koji Shirakawa, Shizuoka-ken (JP); Hidenori Takahashi, Shizuoka-ken (JP); Tomotaka Tsuchimura, Shizuoka-ken (JP)

(73) Assignee: FUJIFILM CORPORATION, Minato-Ku, Tokyo (JP)

(21) Appl. No.: 13/320,116

(22) PCT Filed: May 20, 2010
(86) PCT No.: PCT/JP2010/058943

§ 371 Date: Nov. 11, 2011

(30) Foreign Application Priority Data
May 22, 2009 (JP) 2009-124353
May 29, 2009 (JP) 2009-130405
Jun. 3, 2009 (JP) 2009-134291

(51) Int. Cl. G03F 7/20; G03F 7/027

(52) U.S. Cl. 430/285.1; 430/325; 430/296

(57) ABSTRACT

According to one embodiment, an actinic-ray- or radiation-sensitive resin composition includes a resin (A) whose solubility in an alkali developer is increased by the action of an acid, the resin containing any of the units of general formula (AI) below and any of the units of general formula (AII) below, and a compound (B) that when exposed to actinic rays or radiation, generates an acid with any of the structures of general formula (BI) below.

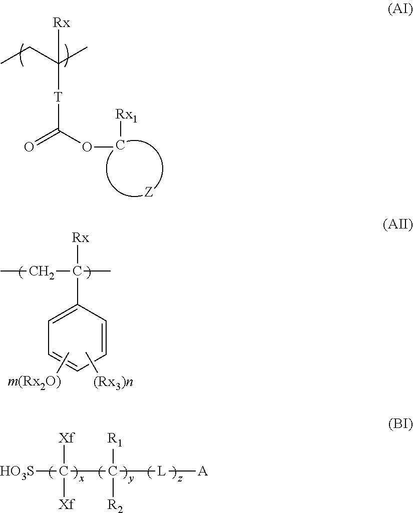

### CROSS-REFERENCE TO RELATED APPLICATIONS

This application is based upon and claims the benefit of priority from prior Japanese Patent Applications No. 2009-124353, filed May 22, 2009; No. 2009-130405, filed May 29, 2009; and No. 2009-134291, filed Jun. 3, 2009, the entire contents of all of which are incorporated herein by reference.

### TECHNICAL FIELD

The present invention relates to an actinic-ray- or radiation-sensitive resin composition suitable for use in the ultramicrolithography process or other photofabrication processes for the production of very-large-scale integrated circuits or large-capacity microchips, etc. and further to a method of forming a pattern using the composition. More particularly, the present invention relates to an actinic-ray- or radiation-sensitive resin composition suitable for use in the microfabrication of semiconductor devices using electron beams, X-rays or EUV light (wavelength: about 13 nm) and further to a method of forming a pattern with the use of the composition.

In the present invention, the terms “actinic rays” and “radiation” mean, for example, brightline spectra from a mercury lamp, far ultraviolet represented by an excimer laser, extreme ultraviolet, X-rays, electron beams and the like. In the present invention, the term “light” means actinic rays or radiation.

### BACKGROUND ART

In the production process for semiconductor devices, such as ICs and LSIs, it is conventional practice to perform the microfabrication by lithography using a photoresist composition. In recent years, the formation of an ultrafine pattern in the submicron region or quarter-micron region is increasingly demanded in accordance with the realization of high integration for integrated circuits. Accordingly, the trend of exposure wavelength toward a short wavelength, for example, from g-rays to i-rays and further to a KrF excimer laser light is seen. Moreover, the development of lithography using electron beams, X-rays or EUV light besides the excimer laser light is now progressing.

This lithography using electron beams, X-rays or EUV light is positioned as the next-generation or next-next-generation pattern forming technology. Resists of high sensitivity and high resolution are demanded for the lithography.

In particular, increasing the sensitivity is a very important task to be attained for the reduction of wafer processing time. However, the pursuit of increasing the sensitivity is likely to invite not only the lowering of resolving power but also the deterioration of line width roughness. Thus, there is a strong demand for the development of resists that simultaneously satisfy the sensitivity and these performances.

Herein, the line width roughness refers to the phenomenon that the edge at an interface of resist pattern and substrate is irregularly varied in the direction perpendicular to the line direction due to the characteristics of the resist, so that when the pattern is viewed from above, the pattern edge is observed uneven. This unevenness is transferred in the etching operation using the resist as a mask to thereby cause poor electrical properties resulting in poor yield.

High sensitivity is in a relationship of trade-off with high resolution, good pattern configuration and good line width roughness. How to simultaneously satisfy all of them is a critical issue.

From the viewpoint of the attainment of high sensitivity, chemical amplification positive resists utilizing an acid-catalyzed reaction have predominantly been studied as a resist suitable for use in such a lithography process using electron beams, X-rays or EUV light. Now, effective use is made of a chemical amplification positive resist composition composed mainly of an acid generator and a phenolic resin with properties such that it is insoluble or poorly soluble in an alkali developer but when acted on by an acid, becomes soluble in the alkali developer (hereinafter simply referred to as “phenolic acid-decomposable resin”).

With respect to these positive resists, some resist compositions containing a phenolic acid-decomposable resin obtained by the copolymerization of an acid-decomposable acrylate monomer are known to now. As such, there can be mentioned, for example, positive resist compositions disclosed in patent references 1 to 4 and the like.

However, for practical application, further enhancements are demanded with respect to the sensitivity, resolution of various circuit patterns, exposure latitude, line width roughness (LWR) and stability against post-exposure time delay in vacuum (PED stability). Additionally, further enhancements are demanded with respect to a bridge margin and isolated space resolvability.

### PRIOR ART REFERENCE

[Patent reference 1] U.S. Pat. No. 5,561,194,
[Patent reference 2] Jpn. Pat. Appln. KOKAI Publication No. (hereinafter referred to as JP-A-) 8-101509,
[Patent reference 3] JP-A-2000-347405, and
[Patent reference 4] JP-A-2004-210803.

### DISCLOSURE OF INVENTION

### Problems to be Solved

It is an object of the present invention to solve the problems of performance-enhancing technology in the microfabrication of semiconductor devices using high-energy rays, X-rays, electron beams or EUV light. It is a particular object of the present invention to provide an actinic-ray- or radiation-sensitive resin composition capable of patterning that is satisfactory with respect to the high sensitivity, high resolution of dense pattern or isolated line, sufficient exposure latitude, good line width roughness, stability against post-exposure time delay in vacuum (PED stability), good bridge margin, high resolution of isolated space, etc. It is a further object of the present invention to provide a method of forming a pattern with the use of the composition.

Herein, the expression “exposure latitude” means that the pattern size is stable even when the exposure amount is varied. When the exposure latitude is satisfactory, the resolution performance is stable and any yield lowering can be avoided.

The expression “stability against post-exposure time delay in vacuum (PED stability)” means that the pattern size is stable even when the patternwise exposed wafer is allowed to stand undisturbed in vacuum for a prolonged period of time after the exposure. When the stability against post-exposure time delay in vacuum is satisfactorily high, the resolution performance is stable and any yield lowering can be avoided.

Further, for the resolution of a pattern entirely exposed therearound, such as an isolated line, it is important to satisfactorily inhibit the diffusion of the acid generated by exposure. When the inhibition of the diffusion of the acid is unsatisfactory, the formation of the isolated line is prevented by the diffusion of the acid from exposed areas.

### Means for Solving the Problems

The inventors have conducted extensive and intensive studies, and as a result have found that the above objects can be attained by the patterning using a resist composition in which a polymer containing a unit with specified structure and an acid generator capable of generating an acid with specified structure are simultaneously contained.

Namely, the present invention is as described below.

(1) An actinic-ray- or radiation-sensitive resin composition comprising a resin (A) whose solubility in an alkali developer is increased by the action of an acid, the resin containing any of the units of general formula (AI) below and any of the units of general formula (AII) below, and a compound (B) that when exposed to actinic rays or radiation, generates an acid with any of the structures of general formula (BI) below,

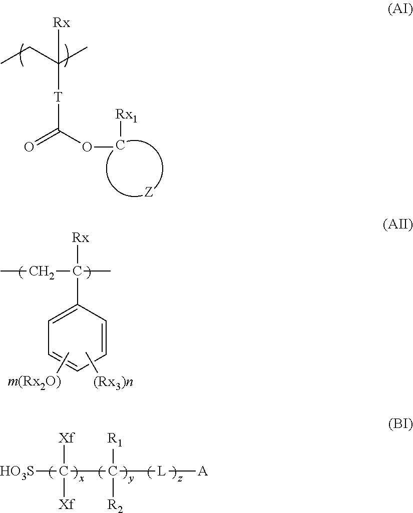

in general formula (AI),

Rx represents a hydrogen atom, a methyl group, a trifluoromethyl group or a hydroxymethyl group;

T represents a single bond or a bivalent connecting group;

Rx₁ represents a linear or branched alkyl group or a monocycloalkyl group; and

Z cooperates with C to thereby form a monocycloalkyl group having 5 to 8 carbon atoms,

in general formula (AII),

Rx represents a hydrogen atom, a methyl group, a trifluoromethyl group or a hydroxymethyl group;

Rx₂ represents a hydrogen atom or an organic group;

Rx₃ represents a non-acid-decomposable group; and

m is an integer of 1 to 4 and n is an integer of 0 to 4, provided that 1≦n+m≦5, and provided that when m is 2 to 4, the plurality of Rx₂s may be identical to or different from each other and when n is 2 to 4, the plurality of Rx₃s may be identical to or different from each other, and

in general formula (BI),

each of Xfs independently represents a fluorine atom or an alkyl group substituted with at least one fluorine atom;

each of R₁ and R₂ independently represents a group selected from among a hydrogen atom, a fluorine atom, an alkyl group and an alkyl group substituted with at least one fluorine atom, provided that R₁s, and also R₂s, may be identical to or different from each other;

L represents a single bond or a bivalent connecting group, provided that Ls may be identical to or different from each other;

A represents a group with a cyclic structure; and

x is an integer of 1 to 20, y an integer of 0 to 10 and z an integer of 0 to 10.

(2) The actinic-ray- or radiation-sensitive resin composition according to item (1), wherein at least one Xf is a fluorine atom in general formula (BI).

(3) An actinic-ray- or radiation-sensitive resin composition comprising a resin (A) whose solubility in an alkali developer is increased by the action of an acid, the resin containing any of the units of general formula (AI) below and any of the units of general formula (AII) below, and a compound (B) that when exposed to actinic rays or radiation, generates an acid with any of the structures of general formulae (BII) and (BIII) below,

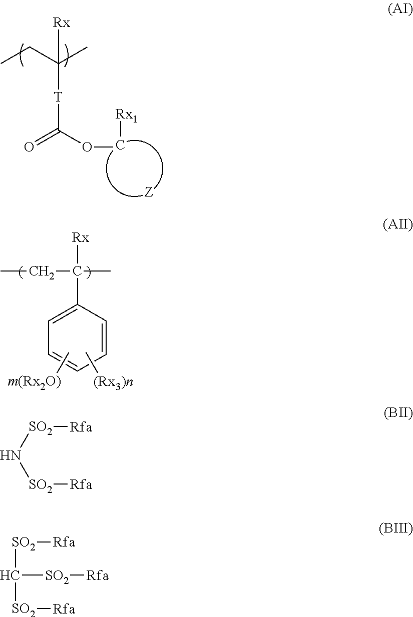

in general formula (AI),

Rx represents a hydrogen atom, a methyl group, a trifluoromethyl group or a hydroxymethyl group;

T represents a single bond or a bivalent connecting group;

Rx₁ represents a linear or branched alkyl group or a monocycloalkyl group; and

Z cooperates with C to thereby form a monocycloalkyl group having 5 to 8 carbon atoms,

in general formula (AII),

Rx represents a hydrogen atom, a methyl group, a trifluoromethyl group or a hydroxymethyl group;

Rx₂ represents a hydrogen atom or an organic group;

Rx₃ represents a non-acid-decomposable group; and

m is an integer of 1 to 4 and n is an integer of 0 to 4, provided that 1≦n+m≧5, and provided that when m is 2 to 4, the plurality of Rx₂s may be identical to or different from each other and when n is 2 to 4, the plurality of Rx₃s may be identical to or different from each other, and

in general formulae (BII) and (BIII),

each of Rfas independently represents a monovalent organic group containing a fluorine atom, provided that the plurality of Rfas may be bonded to each other to thereby form a ring.

(4) An actinic-ray- or radiation-sensitive resin composition comprising a resin (A) whose solubility in an alkali developer is increased by the action of an acid, the resin containing any of the units of general formula (AI) below and any of the units of general formula (AII) below, and a compound (B) that when exposed to actinic rays or radiation, generates an acid with any of the structures of general formula (BIV) below,

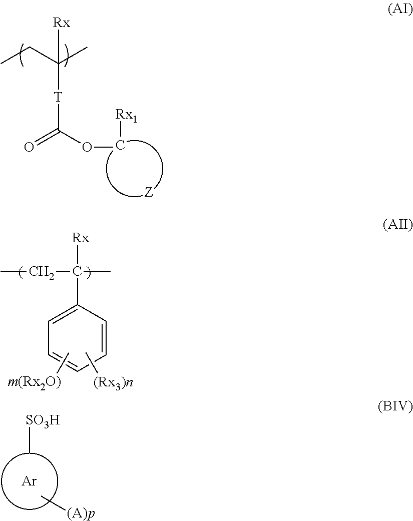

in general formula (AI),

Rx represents a hydrogen atom, a methyl group, a trifluoromethyl group or a hydroxymethyl group;

T represents a single bond or a bivalent connecting group;

Rx₁ represents a linear or branched alkyl group or a monocycloalkyl group; and

Z cooperates with C to thereby form a monocycloalkyl group having 5 to 8 carbon atoms,

in general formula (AII),

Rx represents a hydrogen atom, a methyl group, a trifluoromethyl group or a hydroxymethyl group;

Rx₂ represents a hydrogen atom or an organic group;

Rx₃ represents a non-acid-decomposable group; and

m is an integer of 1 to 4 and n is an integer of 0 to 4, provided that 1≦n+m≦5, and provided that when m is 2 to 4, the plurality of Rx₂s may be identical to or different from each other and when n is 2 to 4, the plurality of Rx₃s may be identical to or different from each other, and

in general formula (BIV),

Ar represents an aromatic ring in which a further substituent other than the A-groups may be introduced;

p is an integer of 1 or greater; and

A represents a group containing a hydrocarbon group having 3 or more carbon atoms, provided that when p is 2 or greater, the plurality of A-groups may be identical to or different from each other.

(5) The actinic-ray- or radiation-sensitive resin composition according to item (4), wherein general formula (BIV), A represents a group containing a hydrocarbon group having 4 or more carbon atoms.

(6) The actinic-ray- or radiation-sensitive resin composition according to item (4), wherein general formula (BIV), A represents a group containing a cyclohydrocarbon group having 4 or more carbon atoms.

(7) The actinic-ray- or radiation-sensitive resin composition according to item (4), wherein general formula (BIV), A represents a group containing a cyclohexyl group.

(8) The actinic-ray- or radiation-sensitive resin composition according to any of items (4) to (7), wherein in general formula (BIV), Ar is a benzene ring and p is an integer of 2 or greater, provided that among the two or more A-groups, two A-groups are placed on the ortho positions to the group —SO₃H and that the carbon atom of each of the A-groups adjacent to Ar is a tertiary or quaternary carbon atom.

(9) The actinic-ray- or radiation-sensitive resin composition according to any of items (4) to (8), wherein in general formula (BIV), as the further substituent other than the A-groups, at least one substituent selected from among a group containing a hydrocarbon group having 1 or more carbon atoms, a halogen atom, a hydroxyl group, a carboxyl group, a cyano group and a nitro group is introduced in the group represented by Ar

(10) The actinic-ray- or radiation-sensitive resin composition according to any of items (1) to (9), wherein the units of general formula (AI) have the structures of general formula (AI-1) below,

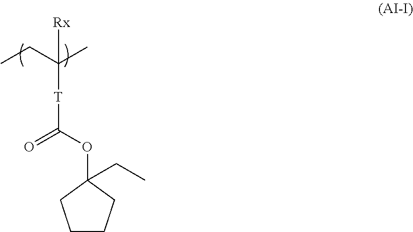

in general formula (AI-1), Rx and T are as defined above in general formula (AI).

(11) The actinic-ray- or radiation-sensitive resin composition according to any of items (1) to (10), further comprising a surfactant with any of the structures of formula (II) below,

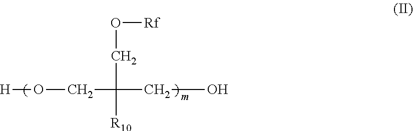

in general formula (II),

R₁₀ represents a hydrogen atom or an alkyl group;

Rf represents a fluoroalkyl group or a fluoroalkylcarbonyl group; and

m is an integer of 1 to 50.

(12) A method of forming a pattern, comprising forming the actinic-ray- or radiation-sensitive resin composition according to any of items (1) to (11) into a film, exposing the film and developing the exposed film.

(13) The method of forming a pattern according to item (12), wherein electron beams, X-rays or EUV light is used as an exposure light source.

The present invention has made it feasible to provide an actinic-ray- or radiation-sensitive resin composition capable of patterning that is satisfactory with respect to the high sensitivity, high resolution of dense pattern or isolated line, sufficient exposure latitude, good line width roughness, stability against post-exposure time delay in vacuum (PED stability), good bridge margin and high resolution of isolated space.

### Mode for Carrying Out the Invention

The present invention will be described in detail below.

With respect to the expression of a group (atomic group) used in this specification, the expression even when there is no mention of “substituted and unsubstituted” encompasses groups not only having no substituent but also having substituents. For example, the expression “alkyl groups” encompasses not only alkyls having no substituent (unsubstituted alkyls) but also alkyls having substituents (substituted alkyls).

### [Actinic-Ray- or Radiation-Sensitive Resin Composition]

### [1] (A) Resin Whose Solubility in an Alkali Developer is Increased by the Action of an Acid

The resin as component (A) is a resin whose solubility in an alkali developer is increased by the action of an acid, especially a resin provided at its principal chain or side chain or both thereof with a group that is decomposed by the action of an acid to thereby generate an alkali-soluble group (hereinafter also referred to as an “acid-decomposable group”).

As preferred alkali-soluble groups, there can be mentioned a carboxyl group, a fluoroalcohol group (preferably hexafluoroisopropanol), a sulfonate group and the like.

The acid-decomposable group is preferably a group as obtained by substituting the hydrogen atom of any of these alkali-soluble groups with an acid-eliminable group.

The resin as component (A) contains, as the repeating unit containing an acid-decomposable group, any of the repeating units of general formula (AI) below.

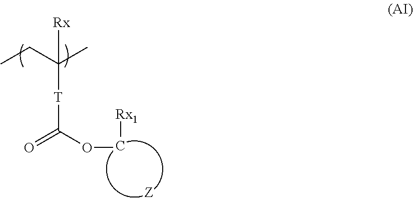

In general formula (AI),

Rx represents a hydrogen atom, a methyl group, a trifluoromethyl group or a hydroxymethyl group.

T represents a single bond or a bivalent connecting group.

Rx₁ represents a linear or branched alkyl group or a monocycloalkyl group.

Z cooperates with C to thereby form a monocycloalkyl group having 5 to 8 carbon atoms.

As the bivalent connecting group represented by T, there can be mentioned an alkylene group, a group of the formula —COO-Rt-, a group of the formula —O-Rt- or the like. In the formulae, Rt represents an alkylene group or a cycloalkylene group.

T is preferably a single bond or a group of the formula —COO-Rt-. Rt is preferably an alkylene group having 1 to 5 carbon atoms, more preferably a —CH₂-group or —(CH₂)₃— group.

The alkyl group represented by Rx₁ is preferably a linear or branched alkyl group having 1 to 4 carbon atoms. A methyl group and an ethyl group are especially preferred. A substituent may be introduced in the alkyl group. As the substituent, there can be mentioned, for example, a halogen atom, a cycloalkyl group, an aryl group, an alkoxy group, an acyl group, —OC(═O)Ra, —OC(═O)ORa, —C(═O)ORa, —C(═O)N(Rb)Ra, —N(Rb)C(═O)Ra, —N(Rb)C(═O)ORa, —N(Rb)SO₂Ra, —SRa, —SO₂Ra, —SO₃Ra, —SO₂N(Rb)Ra or the like. In the formulae, each of Ra and Rb independently represents any of a hydrogen atom, a linear or branched alkyl group (preferably having 1 to 6 carbon atoms) and a mono- or polycycloalkyl group (preferably having 5 to 12 carbon atoms).

The cycloalkyl group represented by Rx₁ is preferably a monocycloalkyl group having 4 to 8 carbon atoms. A substituent may be introduced in the cycloalkyl group. As the substituent, there can be mentioned a halogen atom, an alkyl group, a cycloalkyl group, an aryl group, an alkoxy group, an acyl group, —OC(═O)Ra, —OC(═O)ORa, —C(═O)ORa, —C(═O)N(Rb)Ra, —N(Rb)C(═O)Ra, —N(Rb)C(═O)ORa, —N(Rb)SO₂Ra, —SRa, —SO₂Ra, —SO₃Ra, —SO₂N(Rb)Ra or the like. In the formulae, each of Ra and Rb independently represents any of a hydrogen atom, a linear or branched alkyl group (preferably having 1 to 6 carbon atoms) and a mono- or polycycloalkyl group (preferably having 5 to 12 carbon atoms).

The monocycloalkyl group formed by C and Z is preferably a monocycloalkyl group having 5 or 6 carbon atoms.

As a preferred form of general formula (AI), there can be mentioned general formula (AI-1) below. In this formula, Rx and T are as defined above in connection with general formula (AI).

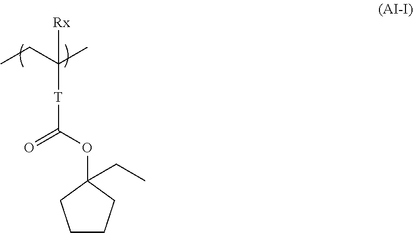

The content of repeating units containing an acid-decomposable group of general formula (AI) based on all the repeating units of the resin (A) is preferably in the range of 10 to 50 mol %, more preferably 20 to 45 mol %.

Specific examples of preferred repeating units containing acid-decomposable groups will be shown below, which however in no way limit the scope of the present invention. In the formulae, Rx represents any of H, CH₃, CF₃ and CH₂OH. Rxa represents a linear or branched alkyl group having 1 to 4 carbon atoms or an optionally substituted cycloalkyl group having 4 to 8 carbon atoms.

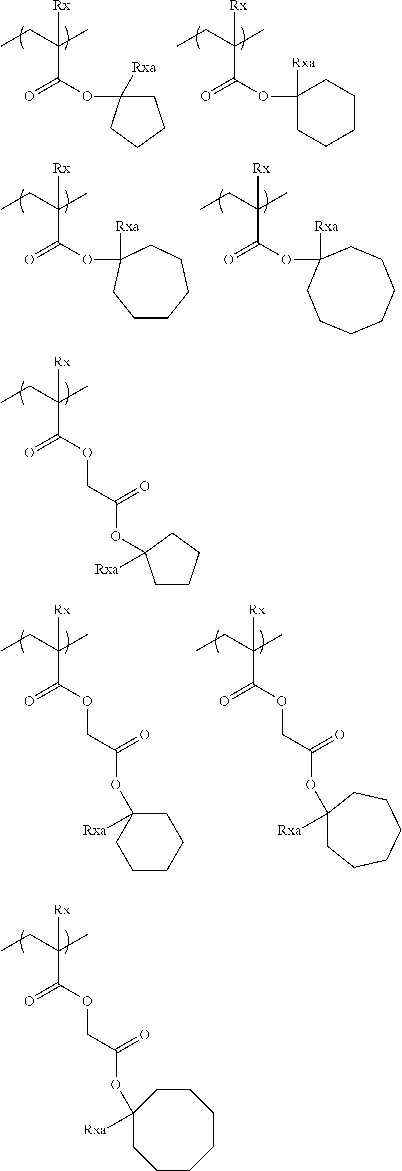

In the present invention, any of the repeating units of general formula (AI) is contained as the repeating unit containing an acid-decomposable group. Further, other repeating units containing an acid-decomposable group may be contained in the present invention.

The resin (A) according to the present invention further contains any of the repeating units of general formula (AII) below.

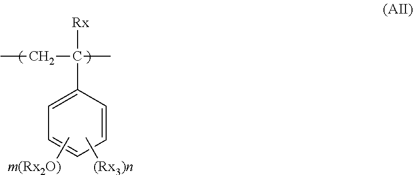

In general formula (AII),

Rx is as defined above in connection with general formula (AI).

Rx₂ represents a hydrogen atom or an organic group.

Rx₃ represents a non-acid-decomposable group.

m is an integer of 1 to 4 and n is an integer of 0 to 4, provided that 1≦n+m≦5, and provided that when m is 2 to 4, the plurality of Rx₂s may be identical to or different from each other and when n is 2 to 4, the plurality of Rx₃s may be identical to or different from each other.

Rx₂ is preferably a hydrogen atom. When m≧2, it is preferred for at least one of the plurality of Rx₂s to be a hydrogen atom.

When Rx₂ is an organic group, it may be an acid-decomposable or non-acid-decomposable one.

As examples of acid-decomposable groups represented by Rx₂, there can be mentioned —C(Rx₂₁)(Rx₂₂)(Rx₂₃), —CO—O-Rx₂₄, —C(Rx₂₅)(Rx₂₆)—O-Rx₂₇ and the like.

In these formulae, each of Rx₂₁ to Rx₂₃ independently represents an alkyl group or a cycloalkyl group, provided that any two thereof may be bonded to each other to thereby form a ring structure.

Rx₂₄ represents an alkyl group or a cycloalkyl group

Each of Rx₂₅ and Rx₂₆ independently represents any of a hydrogen atom, a linear or branched alkyl group and a cycloalkyl group.

Rx₂₇ represents an organic group. It is preferably any of an alkyl group, a cycloalkyl group, an aryl group and an alkyl group substituted with either a cycloalkyl group or an aryl group.

As examples of non-acid-decomposable groups represented by Rx₂, there can be mentioned a halogen atom, an alkyl or cycloalkyl group (excluding an alkyl or cycloalkyl group whose carbon atom adjacent to an oxygen atom is a tertiary carbon), an aryl group, an acyl group, —C(═O)ORa and —C(═O)ORb.

In these formulae, each of Ra and Rb independently represents any of a hydrogen atom, a linear or branched alkyl group (preferably having 1 to 6 carbon atoms) and a mono- or polycycloalkyl group (preferably having 5 to 12 carbon atoms).

As the non-acid-decomposable group represented by Rx₃, there can be mentioned, for example, a halogen atom, an alkyl group, a cycloalkyl group, an aryl group, an alkoxy group, an acyl group, —OC(═O)Ra, —OC(═O)ORa, —C(═O)ORa, —C(═O)N(Rb)Ra, —N(Rb)C(═O)Ra, —N(Rb)C(═O)ORa, —N(Rb)SO₂Ra, —SRa, —SO₂Ra, —SO₃Ra or —SO₂N(Rb) Ra.

In these formulae, each of Ra and Rb independently represents any of a hydrogen atom, a linear or branched alkyl group (preferably having 1 to 6 carbon atoms) and a mono- or polycycloalkyl group (preferably having 5 to 12 carbon atoms).

The content of repeating units of general formula (AII) in the resin (A) based on all the repeating units of the resin (A) is preferably in the range of 5 to 75 mol %, more preferably 20 to 70 mol %.

Containing the repeating units of general formula (AII) within the above range is preferred from the viewpoint of simultaneous enhancements of the adherence to substrate and the resolution.

Examples of particular structures of the repeating units of general formula (AII) will be shown below, which in no way limit the scope of the structures of the repeating units. In the formulae, Rx represents any of H, CH₃, CF₃ and CH₂OH.

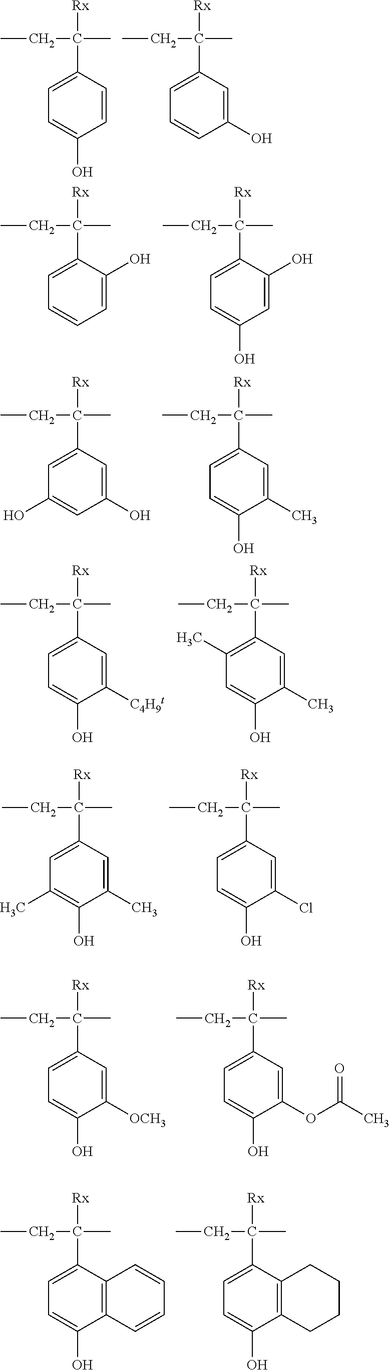

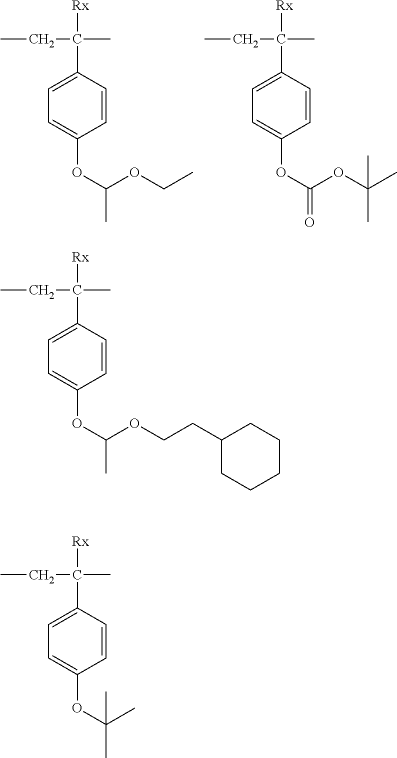

The resin for use in the present invention may further contain any of the repeating units of general formulae (AIII) and (AIV) other than the repeating units of general formulae (AI) and (AII).

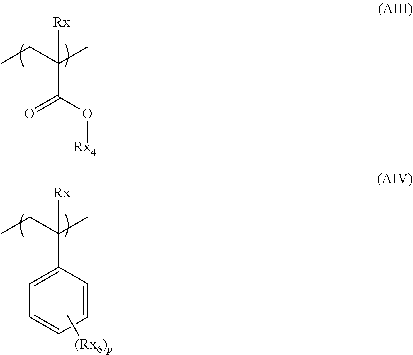

In general formula (AIII),

Rx represents a hydrogen atom, an optionally substituted alkyl group or a group of the formula —CH₂—O—Rx₅. In this formula, Rx₅ represents a hydrogen atom, an alkyl group or an acyl group. Rx is preferably a hydrogen atom, a methyl group, a hydroxymethyl group or a trifluoromethyl group. Among these, a hydrogen atom and a methyl group are especially preferred.

Rx₄ represents an alkyl group having 1 to 8 carbon atoms, a cycloalkyl group having 3 to 12 carbon atoms, a cycloalkenyl group having 3 to 12 carbon atoms or an aryl group.

The cycloalkyl group and cycloalkenyl group represented by Rx₄ are preferably a monocycloalkyl group and monocycloalkenyl group. As preferred monocycloalkyl and monocycloalkenyl groups, there can be mentioned monocyclohydrocarbon groups each having 3 to 7 carbon atoms.

A substituent can further be introduced in the aryl group represented by Rx₄. As the substituent that can further be introduced, there can be mentioned, for example, a halogen atom, an alkyl group, a cycloalkyl group, an aryl group, an alkoxy group, an acyl group, —OC(═O)Ra, —OC(═O)ORa, —C(═O)ORa, —C(═O)N(Rb)Ra, —N(Rb)C(═O)Ra, —N(Rb)C(═O)ORa, —N(Rb)SO₂Ra, —SRa, —SO₂Ra, —SO₃Ra or —SO₂N(Rb)Ra.

In these formulae, each of Ra and Rb independently represents any of a hydrogen atom, a linear or branched alkyl group (preferably having 1 to 6 carbon atoms) and a mono- or polycycloalkyl group (preferably having 5 to 12 carbon atoms).

A substituent may further be introduced in the alkyl group, cycloalkyl group and cycloalkenyl group represented by Rx₄. As preferred substituents, there can be mentioned a halogen atom, a phenyl group, a hydroxyl group protected by a protective group, an amino group protected by a protective group and the like. With respect to the cycloalkyl group and cycloalkenyl group, further, an alkyl group can be mentioned as the substituent. With respect to the alkyl group, further, a cycloalkyl group can be mentioned as the substituent. Preferred halogen atoms are bromine, chlorine and fluorine atoms. Preferred alkyl groups are methyl, ethyl, butyl and t-butyl groups. A further substituent may be introduced in the above alkyl group. As the further substituent, there can be mentioned a halogen atom, an alkyl group, a hydroxyl group protected by a protective group or an amino group protected by a protective group.

As the above protective group, there can be mentioned, for example, an alkyl group, a cycloalkyl group, an aralkyl group, a substituted methyl group, a substituted ethyl group, an acyl group, an alkoxycarbonyl group or an aralkyloxycarbonyl group. Preferred alkyl groups are, for example, those each having 1 to 4 carbon atoms. Preferred substituted methyl groups are, for example, methoxymethyl, methoxythiomethyl, benzyloxymethyl, t-butoxymethyl and 2-methoxyethoxymethyl groups. Preferred substituted ethyl groups are, for example, 1-ethoxyethyl and 1-methyl-1-methoxyethyl groups. Preferred acyl groups are, for example, aliphatic acyl groups each having 1 to 6 carbon atoms, such as formyl, acetyl, propionyl, butyryl, isobutyryl, valeryl and pivaloyl groups. Preferred alkoxycarbonyl groups are, for example, those each having 1 to 4 carbon atoms.

Specific examples of the repeating units of general formula (AIII) will be shown below, which in no way limit the scope of the repeating units. In the specific examples, Rx represents the same substituent as mentioned above.

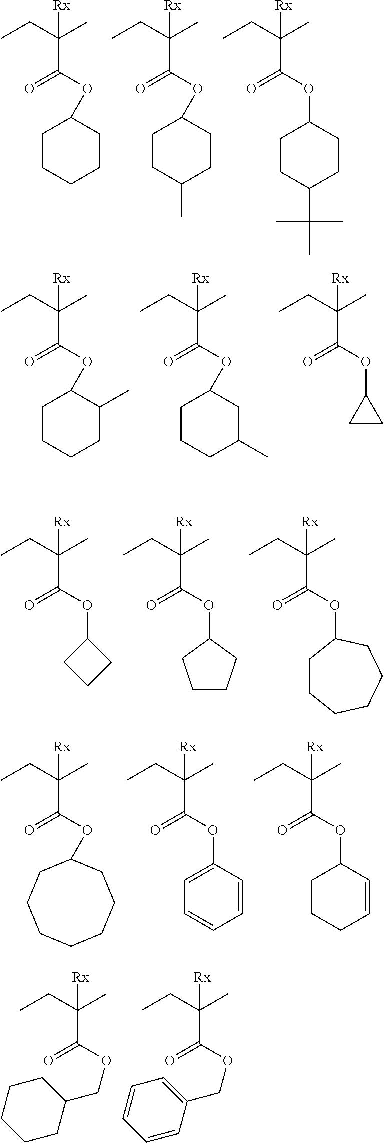

In general formula (AIV),

Rx is as defined above in connection with general formula (AIII).

Rx₆ represents a halogen atom, a cyano group, an acyl group, an alkyl group, an alkoxy group, an acyloxy group, an alkoxycarbonyl group or an aryl group, and

p is an integer of 0 to 5. When p is 2 or greater, the plurality of Rx₆s may be identical to or different from each other.

Rx₆ is preferably an acyloxy group or an alkoxycarbonyl group, more preferably an acyloxy group.

Among the acyloxy groups (general formula: —O—CO-Rx₇, in which Rx₇ represents an alkyl group), those wherein the number of carbon atoms of Rx₇ is in the range of 1 to 6 are preferred, those wherein the number of carbon atoms of Rx₇ is in the range of 1 to 3 are more preferred, and those wherein the number of carbon atoms of Rx₇ is 1 (namely, an acetoxy group) are most preferred.

In general formula, p is preferably 0 to 2, more preferably 1 or 2, and most preferably 1.

A substituent may be introduced in the groups represented by Rx₆. As preferred substituents, there can be mentioned a hydroxyl group, a carboxyl group, a cyano group, a halogen atom (a fluorine atom, a chlorine atom, a bromine atom or an iodine atom), an alkoxy group (a methoxy group, an ethoxy group, a propoxy group, a butoxy group or the like) and the like. With respect to the cyclic structure, further, an alkyl group (preferably having 1 to 8 carbon atoms) can be mentioned as the substituent.

Specific examples of the repeating units of general formula (AIV) will be shown below, which in no way limit the scope of the repeating units. In the following specific examples, Rx represents the same substituent as mentioned above.

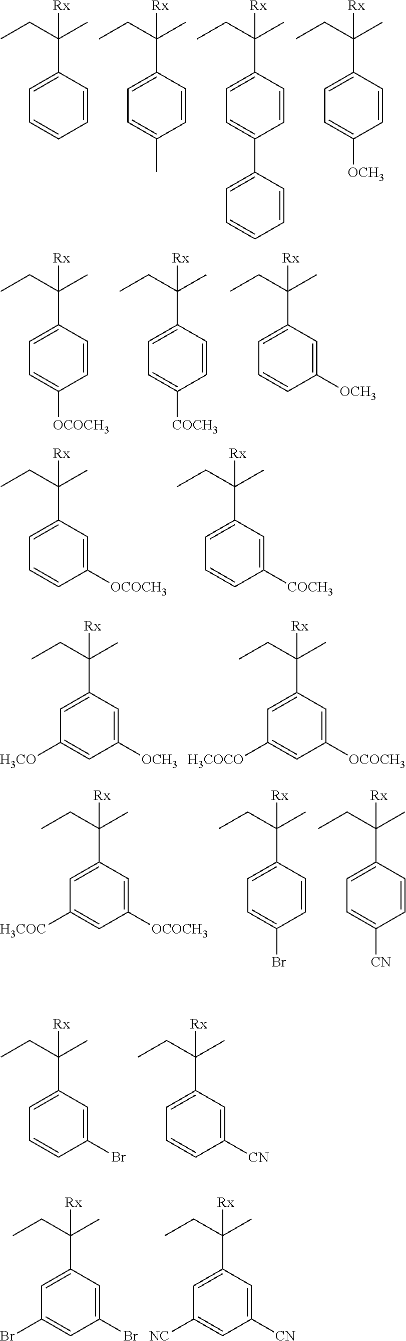

The content of repeating units of general formula (AIII) or (AIV) in the resin (A) based on all the repeating units of the resin (A) is preferably in the range of 0 to 40 mol %, more preferably 0 to 20 mol %.

Particular examples of the resins as component (A) for use in the present invention will be shown below, which however in no way limit the scope of the present invention.

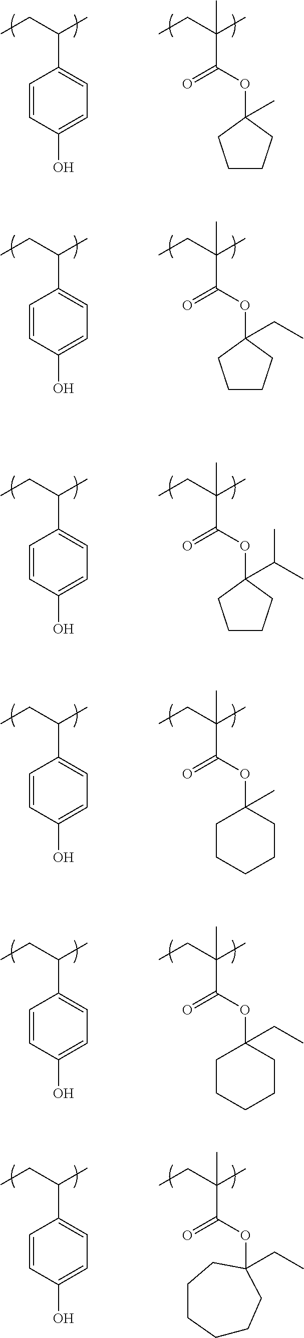

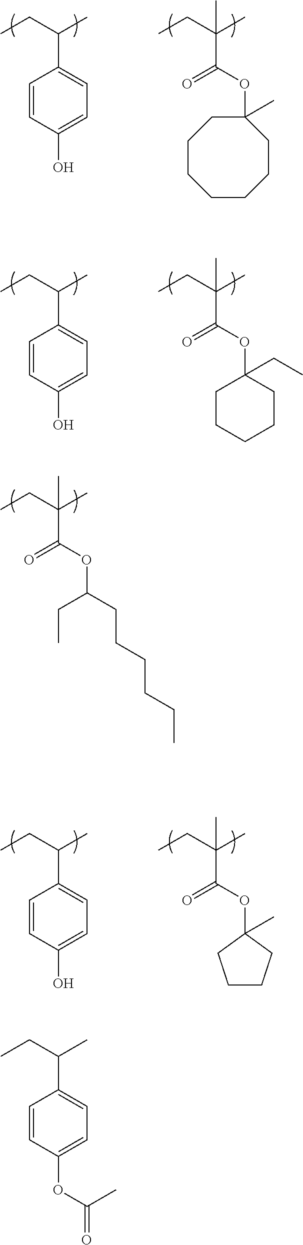

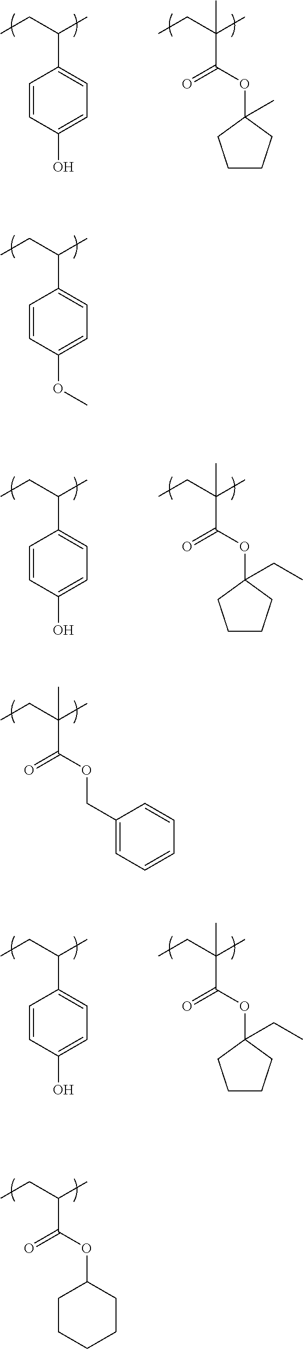

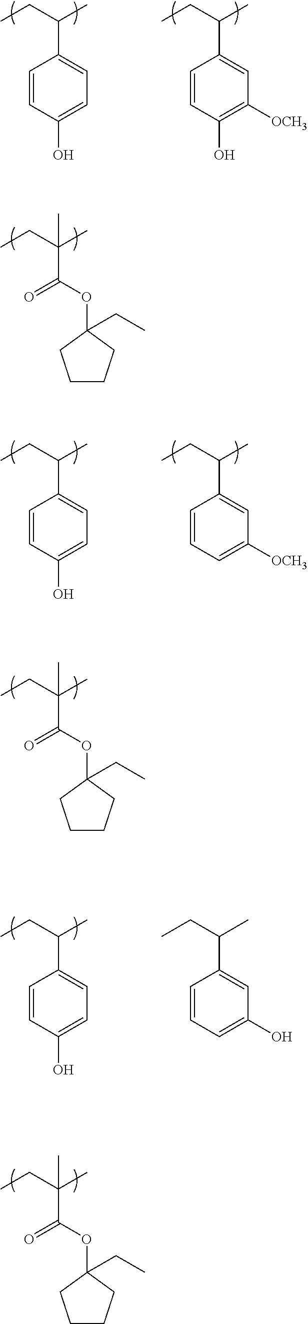

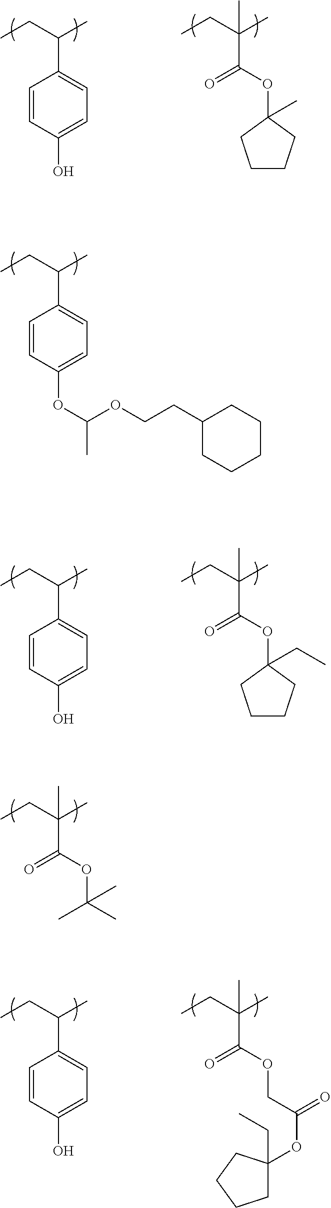

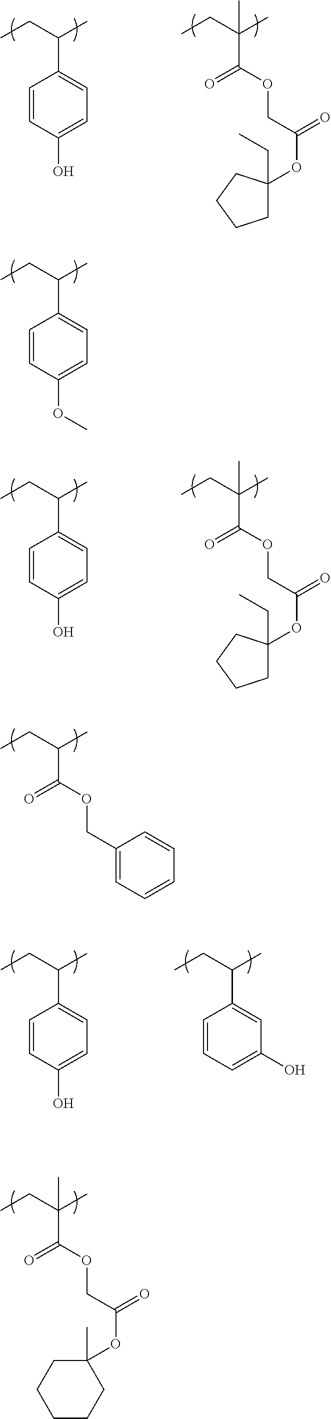

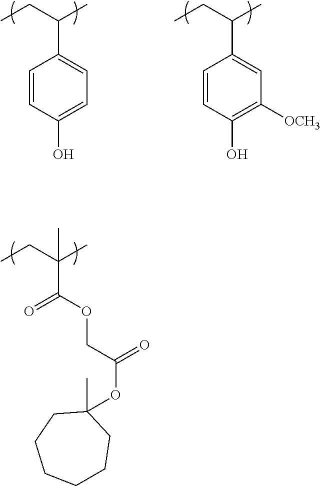

The content of resin (A) in the composition of the present invention based on the total solids thereof is preferably in the range of 50 to 99 mol %, more preferably 70 to 95 mol %.

### [2] (B) Acid Generator

The actinic-ray- or radiation-sensitive resin composition of the present invention contains a compound that when exposed to actinic rays or radiation, generates an acid (hereinafter also referred to as “acid generator”).

In one aspect, the composition of the present invention contains a compound that generates any of the acids of general formula (BI) below as the acid generator.

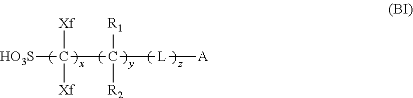

In the general formula,

each of Xfs independently represents a fluorine atom or an alkyl group substituted with at least one fluorine atom.

Each of R₁ and R₂ independently represents a member selected from among a hydrogen atom, a fluorine atom, an alkyl group and an alkyl group substituted with at least one fluorine atom, provided that R₁s, and also R₂s, may be identical to or different from each other.

L represents a single bond or a bivalent connecting group, provided that Ls may be identical to or different from each other.

A represents a group with a cyclic structure; and

x is an integer of 1 to 20, y an integer of 0 to 10 and z an integer of 0 to 10.

General formula (BI) will be described in greater detail below.

The alkyl group as a constituent of the alkyl group substituted with a fluorine atom represented by Xf preferably has 1 to 10 carbon atoms, more preferably 1 to 4 carbon atoms. It is preferred for the alkyl group substituted with a fluorine atom represented by Xf to be a perfluoroalkyl group.

Xf is preferably a fluorine atom or a perfluoroalkyl group having 1 to 4 carbon atoms. In particular, there can be mentioned a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Of these, a fluorine atom and CF₃ are preferred. A fluorine atom is most preferred.

Each of the alkyl group and the alkyl group as a constituent of the alkyl group substituted with at least one fluorine atom, represented by each of R₁ and R₂ preferably has 1 to 4 carbon atoms. Perfluoroalkyl groups each having 1 to 4 carbon atoms are more preferred. In particular, there can be mentioned CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉. Of these, CF₃ is preferred.

In the formula, x is preferably 1 to 8, more preferably 1 to 4; y is preferably 0 to 4, more preferably 0; and z is preferably 0 to 8, more preferably 0 to 4.

The bivalent connecting group represented by L is not particularly limited. As the same, there can be mentioned —COO—, —OCO—, —CO—, —O—, —S—, —SO—, —SO₂—, an alkylene group, a cycloalkylene group, an alkenylene group or the like. Of these, —COO—, —OCO—, —CO—, —O—, —S—, —SO— and —SO₂— are preferred. —COO—, —OCO— and —SO₂— are more preferred.

The group with a cyclic structure represented by A is not particularly limited as long as a cyclic structure is contained. As the group, there can be mentioned an alicyclic group, an aryl group, a group with any of heterocyclic structures (including not only those exhibiting aromaticity but also those exhibiting no aromaticity) or the like.

The alicyclic group may be monocyclic or polycyclic. Preferably, the alicyclic group is a monocycloalkyl group, such as a cyclopentyl group, a cyclohexyl group or a cyclooctyl group, or a polycycloalkyl group, such as a norbornyl group, a tricyclodecanyl group, a tetracyclodecanyl group, a tetracyclododecanyl group or an adamantyl group. Of the mentioned groups, alicyclic groups with a bulky structure having a 6- or more-membered ring are preferred from the viewpoint of inhibiting any in-film diffusion in the step of post-exposure bake (PEB) and enhancing the resolving power and exposure latitude (EL).

As the aryl group, there can be mentioned a benzene ring, a naphthalene ring, a phenanthrene ring or an anthracene ring.

The group with a heterocyclic structure may be an aromatic one or a nonaromatic one. The heteroatom contained therein is preferably a nitrogen atom or an oxygen atom. As particular examples of the heterocyclic structures, there can be mentioned a furan ring, a thiophene ring, a benzofuran ring, a benzothiophene ring, a dibenzofuran ring, a dibenzothiophene ring, a pyridine ring, a piperidine ring, a morpholine ring and the like. Of these, a furan ring, a thiophene ring, a pyridine ring, a piperidine ring and a morpholine ring are preferred.

The above group with a cyclic structure may have a substituent. As the substituent, there can be mentioned an alkyl group (may be linear, branched or cyclic, preferably having 1 to 12 carbon atoms), an aryl group (preferably having 6 to 14 carbon atoms), a hydroxyl group, an alkoxy group, an ester group, an amido group, a urethane group, a ureido group, a thioether group, a sulfonamido group, a sulfonic ester group or the like.

As preferred compounds that generate any of the acids of general formula (BI) when exposed to actinic rays or radiation, there can be mentioned a compound with an ionic structure, such as a sulfonium salt or an iodonium salt, and a compound with a nonionic structure, such as an oxime ester or an imide ester. As the compound with an ionic structure, there can be mentioned any of those of general formulae (ZI) and (ZII) below.

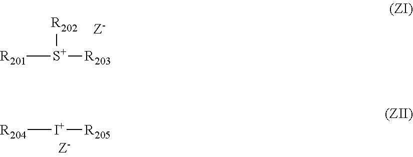

In above general formula (ZI),

each of R₂₀₁, R₂₀₂ and R₂₀₃ independently represents an organic group.

The number of carbon atoms of each of the organic groups represented by R₂₀₁, R₂₀₂ and R₂₀₃ is generally in the range of 1 to 30, preferably 1 to 20.

Two of R₂₀₁ to R₂₀₃ may be bonded to each other to thereby form a ring structure, and the ring within the same may contain an oxygen atom, a sulfur atom, an ester bond, an amido bond or a carbonyl group. As the group formed by bonding of two of R₂₀₁ to R₂₀₃, there can be mentioned an alkylene group (for example, a butylene group or a pentylene group).

As the organic groups represented by R₂₀₁, R₂₀₂ and R₂₀₃, there can be mentioned, for example, corresponding groups of the following compounds (ZI-1), (ZI-2), (ZI-3) and (ZI-4).

Z⁻ represents the anion structure of each of the acids of general formula (BI).

Appropriate use may be made of compounds with two or more of the structures of general formula (ZI). For example, use may be made of compounds having a structure wherein at least one of R₂₀₁ to R₂₀₃ of a compound of general formula (ZI) is bonded directly or via a bivalent connecting group to at least one of R₂₀₁ to R₂₀₃ of another compound of general formula (ZI).

As preferred (ZI) components, there can be mentioned the following compounds (ZI-1), (ZI-2), (ZI-3) and (ZI-4).

Compounds (ZI-1) are arylsulfonium compounds of general formula (ZI) wherein at least one of R₂₀₁ to R₂₀₃ is an aryl group, namely, compounds containing an arylsulfonium as a cation.

In the arylsulfonium compounds, all of the R₂₀₁ to R₂₀₃ may be aryl groups. It is also appropriate that the R₂₀₁ to R₂₀₃ are partially an aryl group and the remainder is an alkyl group or a cycloalkyl group.

As the arylsulfonium compounds, there can be mentioned, for example, a triarylsulfonium compound, a diarylalkylsulfonium compound, an aryldialkylsulfonium compound, a diarylcycloalkylsulfonium compound and an aryldicycloalkylsulfonium compound.

The aryl group of the arylsulfonium compounds is preferably a phenyl group or a naphthyl group, more preferably a phenyl group. The aryl group may be one having a heterocyclic structure containing an oxygen atom, a nitrogen atom, a sulfur atom or the like. As the aryl group having a heterocyclic structure, there can be mentioned, for example, a pyrrole residue, a furan residue, a thiophene residue, an indole residue, a benzofuran residue, a benzothiophene residue or the like. When the arylsulfonium compound has two or more aryl groups, the two or more aryl groups may be identical to or different from each other.

The alkyl group or cycloalkyl group contained in the arylsulfonium compound according to necessity is preferably a linear or branched alkyl group having 1 to 15 carbon atoms or a cycloalkyl group having 3 to 15 carbon atoms. As such, there can be mentioned, for example, a methyl group, an ethyl group, a propyl group, an n-butyl group, a sec-butyl group, a t-butyl group, a cyclopropyl group, a cyclobutyl group, a cyclohexyl group or the like.

The aryl group, alkyl group or cycloalkyl group represented by R₂₀₁ to R₂₀₃ may have as its substituent an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxyl group or a phenylthio group. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. More preferred substituents are an alkyl group having 1 to 4 carbon atoms and an alkoxy group having 1 to 4 carbon atoms. The substituents may be contained in any one of the three R₂₀₁ to R₂₀₃, or alternatively may be contained in all three of R₂₀₁ to R₂₀₃. When R₂₀₁ to R₂₀₃ represent an aryl group, the substituent preferably lies at the p-position of the aryl group.

Now, compounds (ZI-2) will be described.

Compounds (ZI-2) are compounds of formula (ZI) wherein each of R₂₀₁ to R₂₀₃ independently represents an organic group having no aromatic ring. The aromatic rings include an aromatic ring having a heteroatom.

The organic group having no aromatic ring represented by R₂₀₁ to R₂₀₃ generally has 1 to 30 carbon atoms, preferably 1 to 20 carbon atoms.

Preferably, each of R₂₀₁ to R₂₀₃ independently represents an alkyl group, a cycloalkyl group, an allyl group or a vinyl group. More preferred groups are a linear or branched 2-oxoalkyl group, a 2-oxocycloalkyl group and an alkoxycarbonylmethyl group. Especially preferred is a linear or branched 2-oxoalkyl group.

As preferred alkyl groups and cycloalkyl groups represented by R₂₀₁ to R₂₀₃, there can be mentioned a linear or branched alkyl group having 1 to 10 carbon atoms (for example, a methyl group, an ethyl group, a propyl group, a butyl group or a pentyl group) and a cycloalkyl group having 3 to 10 carbon atoms (a cyclopentyl group, a cyclohexyl group or a norbornyl group). As more preferred alkyl groups, there can be mentioned a 2-oxoalkyl group and an alkoxycarbonylmethyl group. As more preferred cycloalkyl group, there can be mentioned a 2-oxocycloalkyl group.

The 2-oxoalkyl group may be linear or branched. A group having >C═O at the 2-position of the alkyl group is preferred.

The 2-oxocycloalkyl group is preferably a group having >C═O at the 2-position of the cycloalkyl group.

As preferred alkoxy groups of the alkoxycarbonylmethyl group, there can be mentioned alkoxy groups having 1 to 5 carbon atoms (a methoxy group, an ethoxy group, a propoxy group, a butoxy group and a pentoxy group).

The R₂₀₁ to R₂₀₃ may be further substituted with a halogen atom, an alkoxy group (for example, 1 to 5 carbon atoms), a hydroxyl group, a cyano group or a nitro group.

Compounds (ZI-3) are those represented by the following general formula (ZI-3) which have a phenacylsulfonium salt structure.

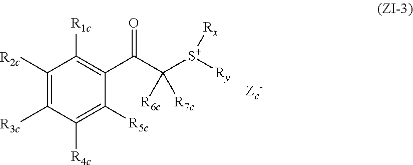

In general formula (ZI-3), each of R_{1c} to R_{5c} independently represents a hydrogen atom, a linear or branched alkyl group (preferably having 1 to 12 carbon atoms), a cycloalkyl group (preferably having 3 to 8 carbon atoms), a linear alkoxy group (preferably having 1 to 12 carbon atoms), a branched alkoxy group (preferably having 3 to 8 carbon atoms) or a halogen atom.

Each of R_{6c} and R_{7c} independently represents a hydrogen atom, a linear or branched alkyl group (preferably having 1 to 12 carbon atoms) or a cycloalkyl group (preferably having 3 to 8 carbon atoms).

Each of Rₓ and R_{y} independently represents a linear or branched alkyl group (preferably having 1 to 12 carbon atoms), a cycloalkyl group (preferably having 3 to 8 carbon atoms), an allyl group or a vinyl group.

Any two or more of R_{1c} to R_{5c}, and R_{6c} and R_{7c}, and Rₓ and R_{y} may be bonded to each other to thereby form a ring structure. This ring structure may contain an oxygen atom, a sulfur atom, an ester bond or an amido bond.

Zc⁻ represents the anion structure of each of the acids of general formula (BI) as mentioned with respect to the Z⁻.

As preferred particular examples of the compounds (ZI-3), there can be mentioned the compounds set forth in sections 0047 and 0048 of JP-A-2004-233661, the compounds set forth in sections 0040 to 0046 of JP-A-2003-35948, the compounds of formula (I-1) to (1-70) shown as examples in US 2003/0224288 A1, the compounds of formulae (IA-1) to (IA-54) and (IB-1) to (IB-24) shown as examples in US 2003/0077540 A1 and the like.

The compounds (ZI-4) are those of general formula (ZI-4) below.

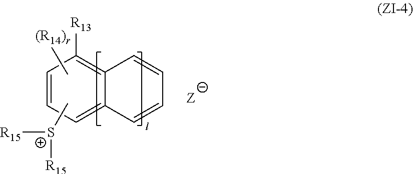

In the general formula (ZI-4),

R₁₃ represents a hydrogen atom, a fluorine atom, a hydroxyl group, an alkyl group, a cycloalkyl group, an alkoxy group or an alkoxycarbonyl group.

R₁₄, each independently in the presence of two or more groups, represents an alkyl group, a cycloalkyl group, an alkoxy group, an alkylsulfonyl group or a cycloalkylsulfonyl group.

Each of R₁₅s independently represents an alkyl group or a cycloalkyl group, provided that the two R₁₅s may be bonded to each other to thereby form a ring.

l is an integer of 0 to 2.

r is an integer of 0 to 8.

Z⁻ represents the anion structure of each of the acids of general formula (BI).

In general formula (ZI-4), the alkyl groups represented by R₁₃, R₁₄ and R₁₅ may be linear or branched and preferably each have 1 to 10 carbon atoms.

As preferred cycloalkyl groups represented by R₁₃, R₁₄ and R₁₅, there can be mentioned a monocyclic alkyl group having 3 to 8 carbon atoms.

The alkoxy groups represented by R₁₃ and R₁₄ may be linear or branched and preferably each have 1 to 10 carbon atoms. Of these alkoxy groups, a methoxy group, an ethoxy group, an n-propoxy group, an n-butoxy group and the like are especially preferred.

The alkoxycarbonyl group represented by R₁₃ may be linear or branched and preferably has 2 to 11 carbon atoms. Of these alkoxycarbonyl groups, a methoxycarbonyl group, an ethoxycarbonyl group, an n-butoxycarbonyl group and the like are especially preferred.

The alkylsulfonyl and cycloalkylsulfonyl groups represented by R₁₄ may be linear, branched or cyclic and preferably each have 1 to 10 carbon atoms. Of these alkylsulfonyl and cycloalkylsulfonyl groups, a methanesulfonyl group, an ethanesulfonyl group, an n-propanesulfonyl group, an n-butanesulfonyl group, a cyclopentanesulfonyl group, a cyclohexanesulfonyl group and the like are preferred.

In the formula, r is preferably 0 to 2.

The cyclic structure that may be formed by the bonding of the two R₁₅s to each other is preferably a 5- or 6-membered ring, especially a 5-membered ring (namely, a tetrahydrothiophene ring) formed by two bivalent R₁₅s in cooperation with the sulfur atom of the general formula (ZI-4). The bivalent R₁₅s may have substituents. As such substituents, there can be mentioned, for example, a hydroxyl group, a carboxyl group, a cyano group, a nitro group, an alkoxy group, an alkoxyalkyl group, an alkoxycarbonyl group, an alkoxycarbonyloxy group and the like as mentioned above. It is especially preferred for the R₁₅ of the general formula (ZI-4) to be a methyl group, an ethyl group, the above-mentioned bivalent group allowing two R₁₅s to be bonded to each other so as to form a tetrahydrothiophene ring structure in cooperation with the sulfur atom of the general formula (ZI-4), or the like.

Now, general formula (ZII) will be described.

In general formula (ZII), each of R₂₀₄ and R₂₀₅ independently represents an aryl group, an alkyl group or a cycloalkyl group.

The aryl group, alkyl group and cycloalkyl group represented by each of R₂₀₄ and R₂₀₅ are the same as mentioned above as the aryl group, alkyl group and cycloalkyl group represented by each of R₂₀₁ to R₂₀₃ of the compounds (ZI-1).

The aryl group, alkyl group and cycloalkyl group represented by each of R₂₀₄ and R₂₀₅ may have substituents. The substituents are the same as those that may be introduced in the aryl group, alkyl group and cycloalkyl group represented by each of R₂₀₁ to R₂₀₃ of the compounds (ZI-1).

Z⁻ represents the anion structure of each of the acids of general formula (BI).

Specific examples of the compounds that generate the acids of general formula (BI) will be shown below.

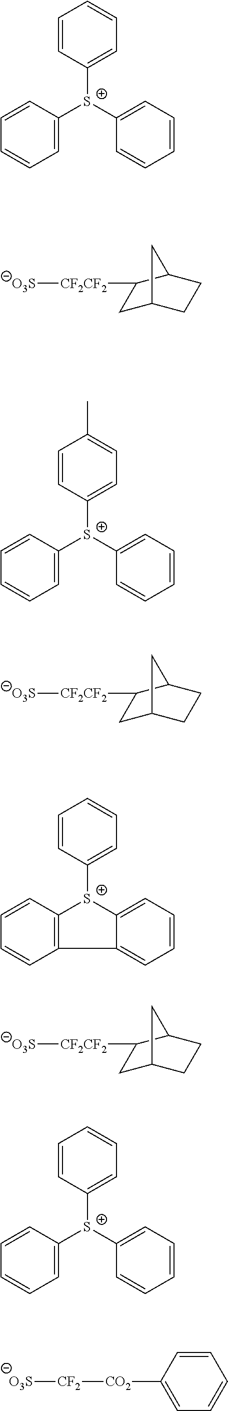

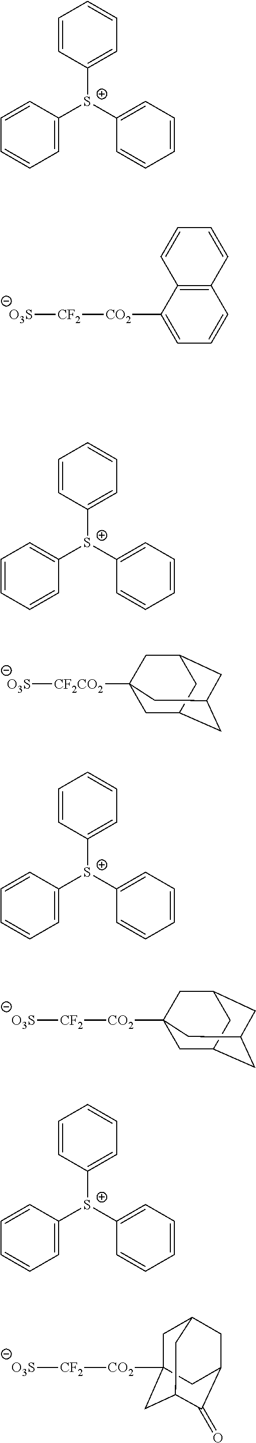

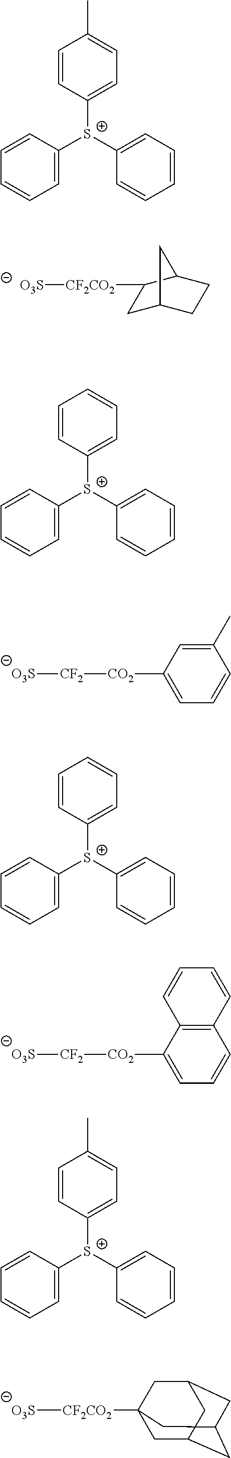

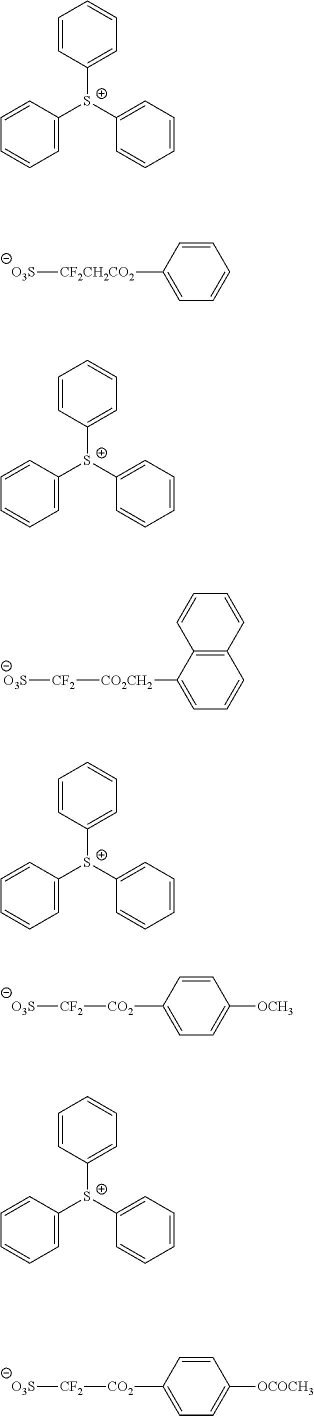

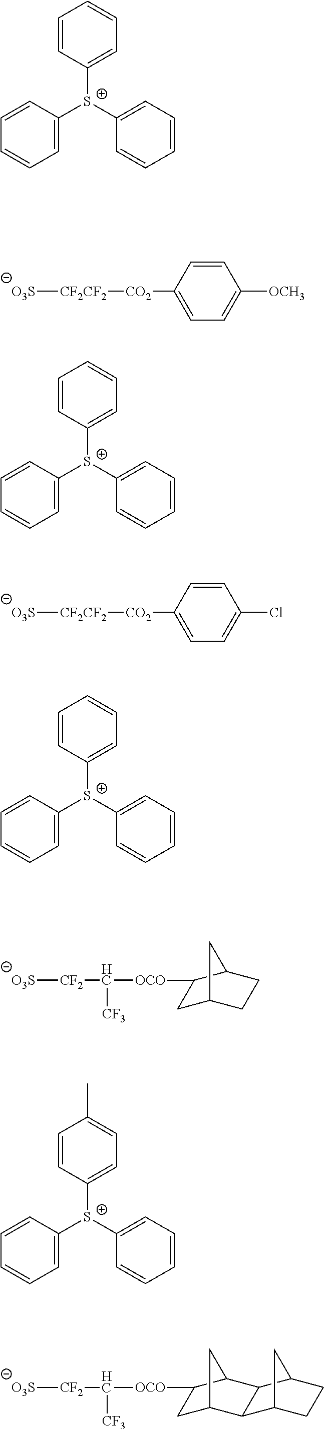

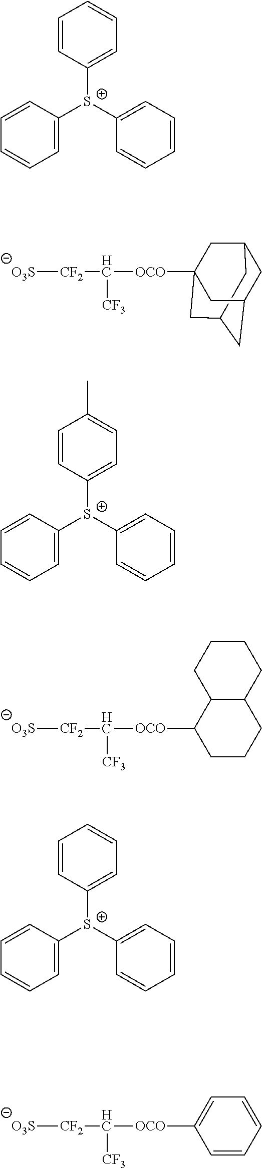

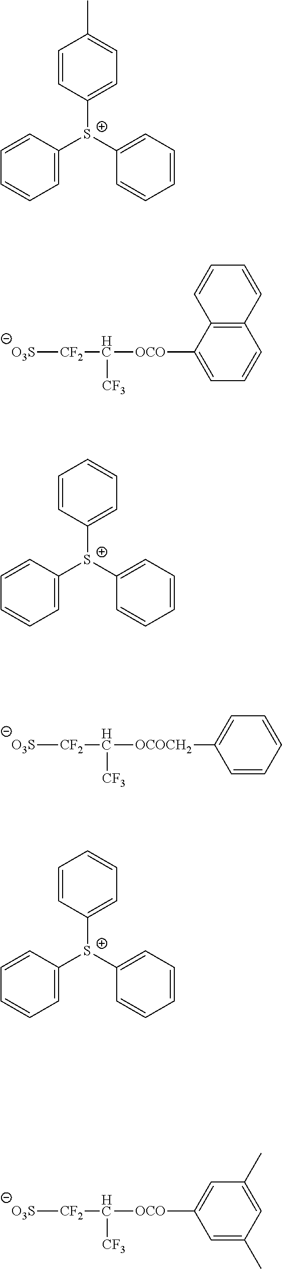

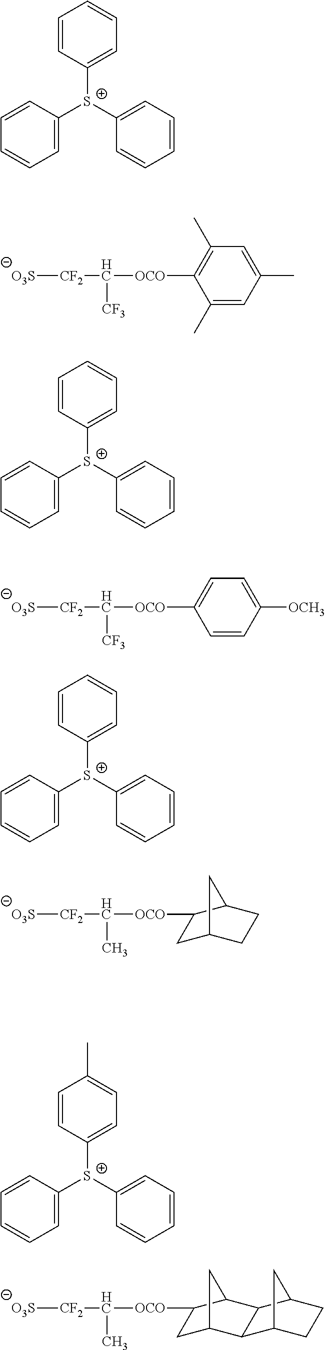

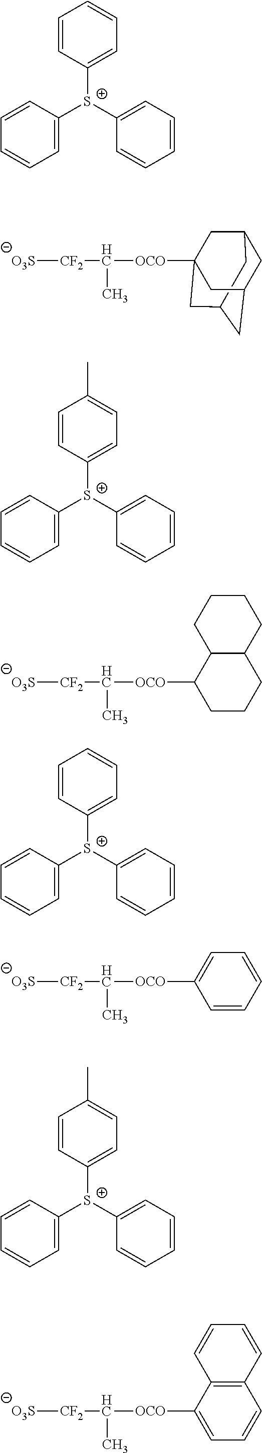

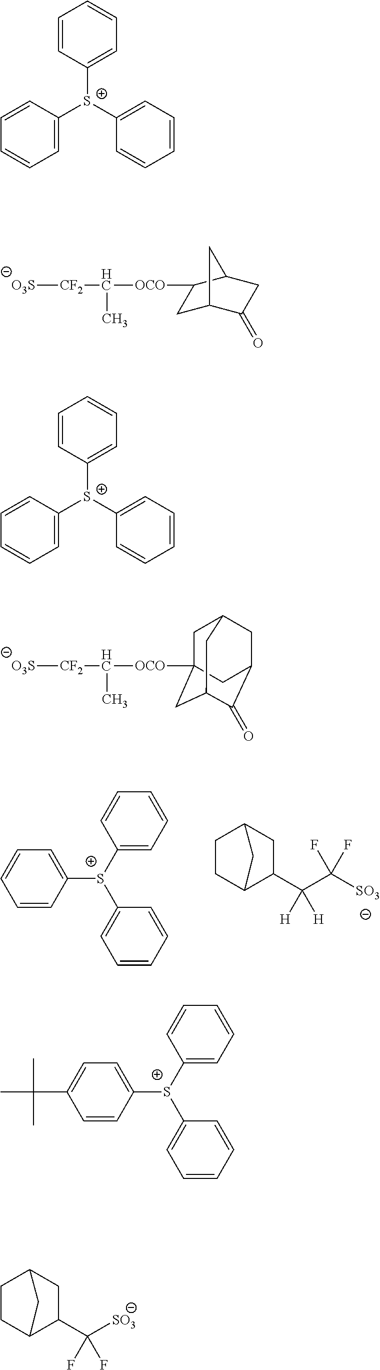

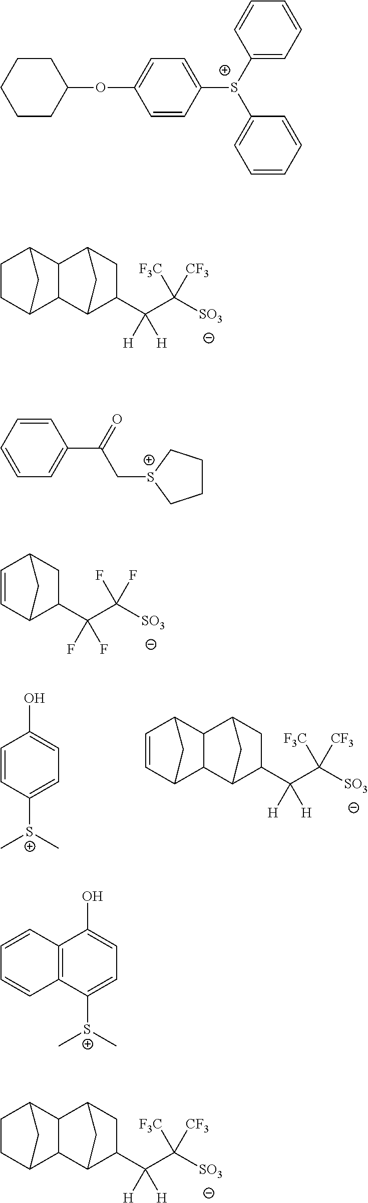

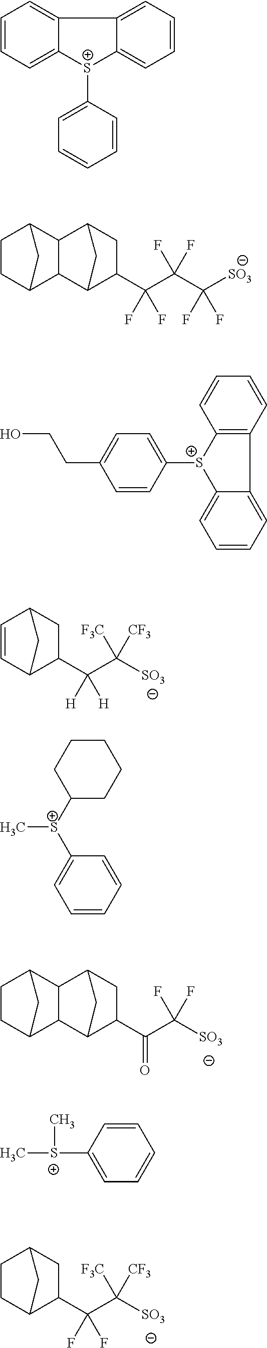

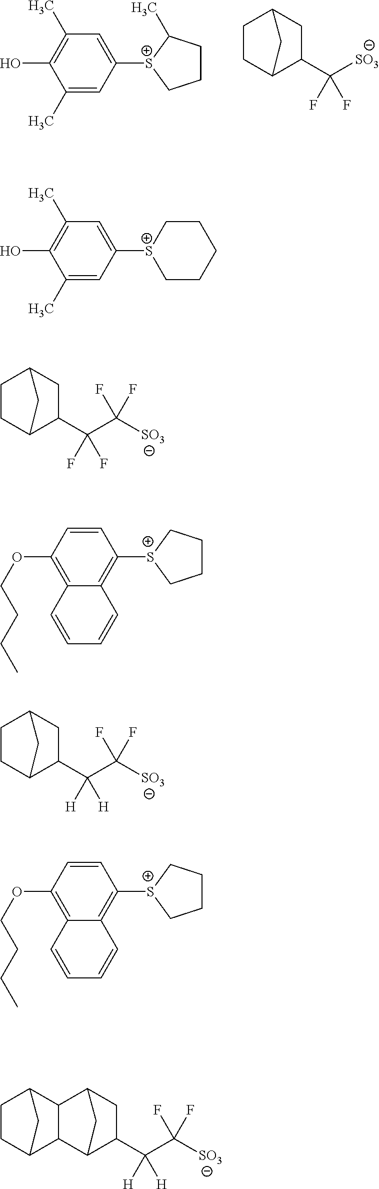

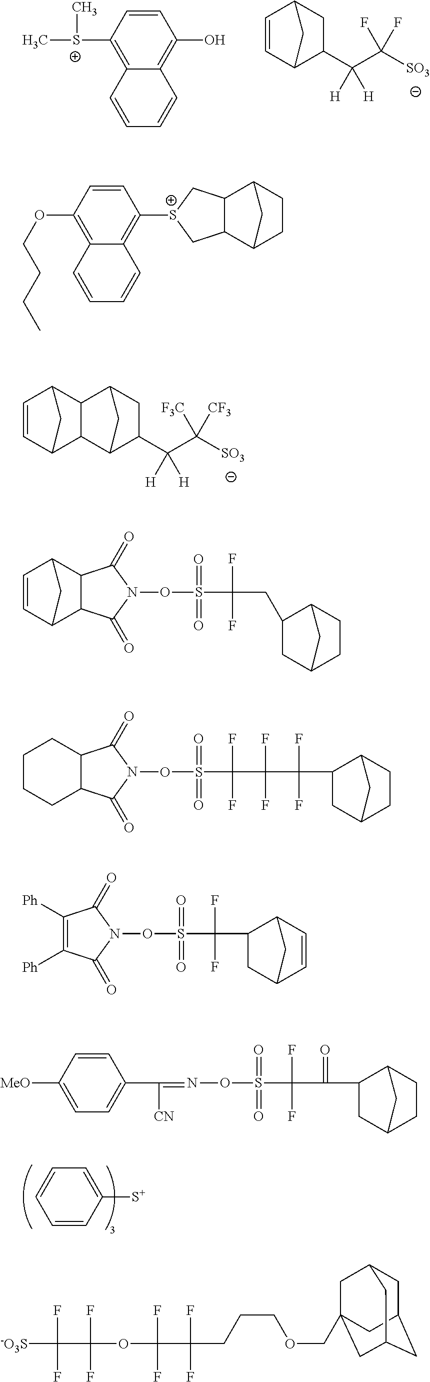

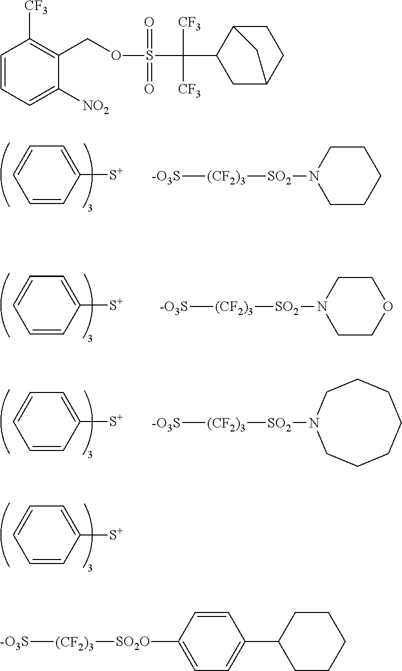

The content of acid generators that generate the acids of general formula (BI) in the composition of the present invention based on the total solids thereof is preferably in the range of 0.1 to 20 mass %, more preferably 1 to 18 mass % and further more preferably 5 to 15 mass %.

The acid generators that generate the acids of general formula (BI) can be used individually or in combination.

In another aspect, the actinic-ray- or radiation-sensitive resin composition of the present invention contains a compound that generates any of the acids of general formula (BIV) as the acid generator.

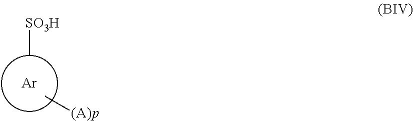

In general formula (BIV),

Ar represents an aromatic ring in which a further substituent other than the A-groups may be introduced;

p is an integer of 1 or greater; and

A represents a group containing a hydrocarbon group having 3 or more carbon atoms, provided that when p is 2 or greater, the plurality of A-groups may be identical to or different from each other.

General formula (BIV) will be described in greater detail below.

The aromatic ring represented by Ar is preferably one having 6 to 30 carbon atoms.

In particular, as the aromatic ring, there can be mentioned a benzene ring, a naphthalene ring, a pentalene ring, an indene ring, an azulene ring, a heptalene ring, an indecene ring, a perylene ring, a pentacene ring, an acenaphthalene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an iodolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, a phenazine ring or the like. Of these, a benzene ring, a naphthalene ring and an anthracene ring are preferred. A benzene ring is more preferred.

As the further substituent other than A-groups that may be introduced in the aromatic ring, there can be mentioned a group containing a hydrocarbon group having 1 or more carbon atoms, a halogen atom (a fluorine atom, a chlorine atom, a bromine atom an iodine atom or the like), a hydroxyl group, a cyano group, a nitro group, a carboxyl group or the like. As the group containing a hydrocarbon group having 1 or more carbon atoms, there can be mentioned, for example, an alkoxy group such as a methoxy group, an ethoxy group or a tert-butoxy group, an aryloxy group such as a phenoxy group or a p-tolyloxy group, an alkylthioxy group such as a methylthioxy group, an ethylthioxy group or a tert-butylthioxy group, an arylthioxy group such as a phenylthioxy group or a p-tolylthioxy group, an alkoxycarbonyl group such as a methoxycarbonyl group or a butoxycarbonyl group, an aryloxycarbony group such as a phenoxycarbonyl group, an acetoxy group, a linear or branched alkyl group such as a methyl group, an ethyl group, a propyl group, a butyl group, a heptyl group, a hexyl group, a dodecyl group or a 2-ethylhexyl group, an alkenyl group such as a vinyl group, a propenyl group or a hexenyl group, an alkynyl group such as an acetylene group, a propynyl group or a hexynyl group, an aryl group such as a phenyl group or a tolyl group, an acyl group such as a benzoyl group, an acetyl group or a toluoyl group, or the like. When two or more such substituents are introduced, at least two of the substituents may be bonded to each other to thereby form a ring.

As the hydrocarbon group contained in the group containing a hydrocarbon group having 3 or more carbon atoms, represented by A, there can be mentioned a noncyclic hydrocarbon group or a cycloaliphatic group.

The A-group in its one aspect is a group containing a hydrocarbon group having 4 or more carbon atoms, and in its another aspect is a group containing a cyclohydrocarbon group having 4 or more carbon atoms.

It is preferred for the carbon atom of each of the A-groups adjacent to Ar to be a tertiary or quaternary carbon atom.

As the noncyclic hydrocarbon groups as A-groups, there can be mentioned an isopropyl group, a t-butyl group, a t-pentyl group, a neopentyl group, a s-butyl group, an isobutyl group, an isohexyl group, a 3,3-dimethylpentyl group, a 2-ethylhexyl group and the like. With respect to the upper limit of the number of carbon atoms of the noncyclic hydrocarbon groups, the number is preferably 12 or less, more preferably 10 or less.

As the cycloaliphatic groups as A-groups, there can be mentioned a cycloalkyl group such as a cyclobutyl group, a cyclopentyl group, a cyclohexyl group, a cycloheptyl group or a cyclooctyl group, an adamantyl group, a norbornyl group, a bornyl group, a camphenyl group, a decahydronaphthyl group, a tricyclodecanyl group, a tetracyclodecanyl group, a camphoroyl group, a dicyclohexyl group, a pinenyl group and the like. Of these cycloaliphatic groups, a cyclohexyl group is especially preferred. The cycloaliphatic groups may have substituents. With respect to the upper limit of the number of carbon atoms of the cycloaliphatic groups, the number is preferably 15 or less, more preferably 12 or less.

As substituents that may be introduced in the noncyclic hydrocarbon groups and cycloaliphatic groups, there can be mentioned, for example, a halogen atom such as a fluorine atom, a chlorine atom, a bromine atom or an iodine atom, an alkoxy group such as a methoxy group, an ethoxy group or a tert-butoxy group, an aryloxy group such as a phenoxy group or a p-tolyloxy group, an alkylthioxy group such as a methylthioxy group, an ethylthioxy group or a tert-butylthioxy group, an arylthioxy group such as a phenylthioxy group or a p-tolylthioxy group, an alkoxycarbonyl group such as a methoxycarbonyl group or a butoxycarbonyl group, an aryloxycarbony group such as a phenoxycarbonyl group, an acetoxy group, a linear or branched alkyl group such as a methyl group, an ethyl group, a propyl group, a butyl group, a heptyl group, a hexyl group, a dodecyl group or a 2-ethylhexyl group, a cycloalkyl group such as a cyclohexyl group, an alkenyl group such as a vinyl group, a propenyl group or a hexenyl group, an alkynyl group such as an acetylene group, a propynyl group or a hexynyl group, an aryl group such as a phenyl group or a tolyl group, a hydroxyl group, a carboxyl group, a sulfonate group, a carbonyl group, a cyano group, and the like.

Specific examples of the cycloaliphatic groups and noncyclic hydrocarbon groups as A-groups will be shown below.

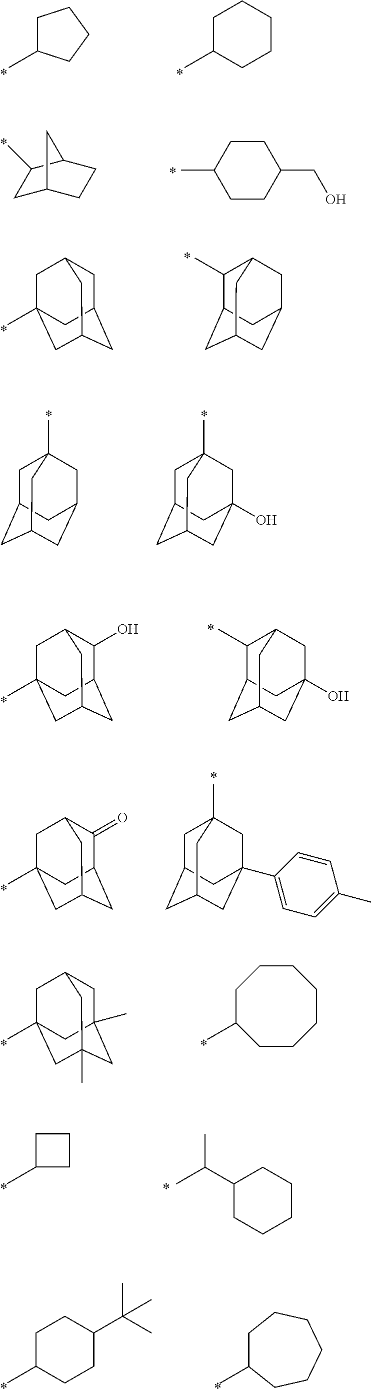

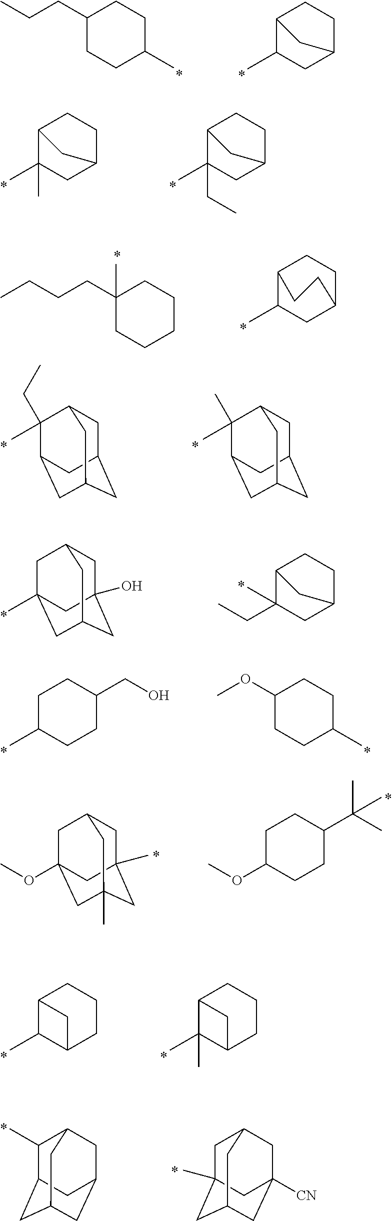

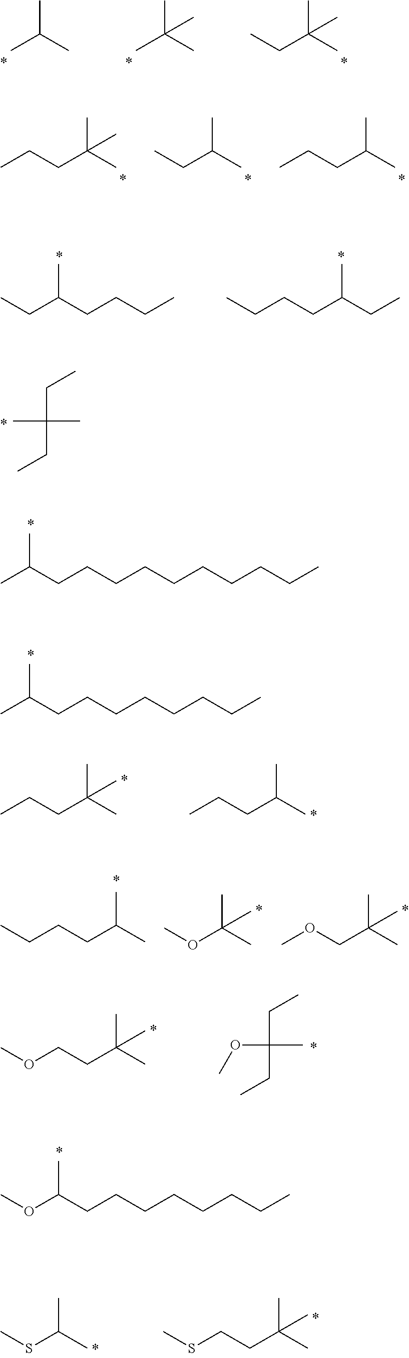

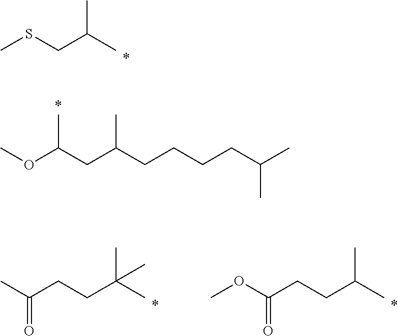

The following structures are preferred among the above from the viewpoint of inhibiting any acid diffusion.

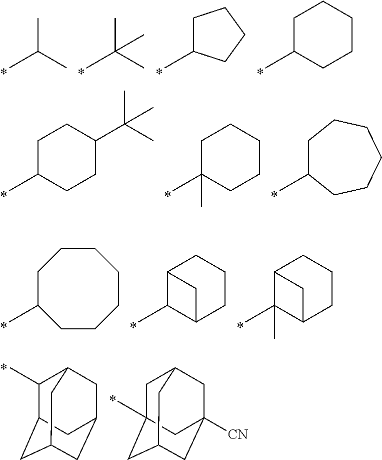

In the formula, p is an integer of 1 or greater. There is no upper limit therefor as long as the number is chemically practicable. However, 1 to 3 are preferred, and 2 or 3 is more preferred, from the viewpoint of inhibiting any acid diffusion.

The structure in which the A-group substitution occurs at least one o-position to the sulfonic acid group is preferred, and the structure in which the A-group substitution occurs at two o-positions is more preferred, from the viewpoint of inhibiting any acid diffusion.

The acids with the structures of general formula (BIV) in one form thereof are expressed by general formula (BV) below.

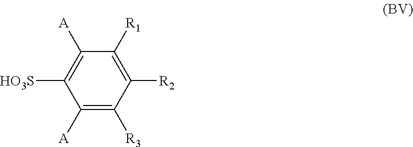

In the general formula, A is as defined above in connection with general formula (BIV). Two As may be identical to or different from each other. Each of R₁ to R₃ independently represents a hydrogen atom, a group containing a hydrocarbon group having 1 or more carbon atoms, a halogen atom, a hydroxyl group, a cyano group or a nitro group. Specific examples of such hydrocarbon groups each having 1 or more carbon atoms are as set forth above.

As preferred compounds that generate the acids of general formula (BIV) when exposed to actinic rays or radiation, there can be mentioned a compound with an ionic structure, such as a sulfonium salt or an iodonium salt, and a compound with a nonionic structure, such as an oxime ester or an imide ester. As the compound with an ionic structure, there can be mentioned any of those of general formulae (ZI′) and (ZII′) below.

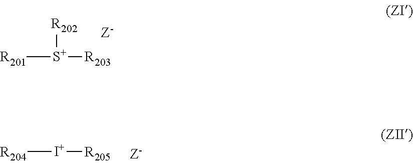

In general formulae (ZI′) and (ZII′),

R₂₀₁ to R₂₀₅ are as defined above in connection with general formulae (ZI) and (ZII).

Z⁻ represents the anion structure of each of the acids of general formula (IV).

Specific examples of the compounds that generate the acids of general formula (BIV) will be shown below.

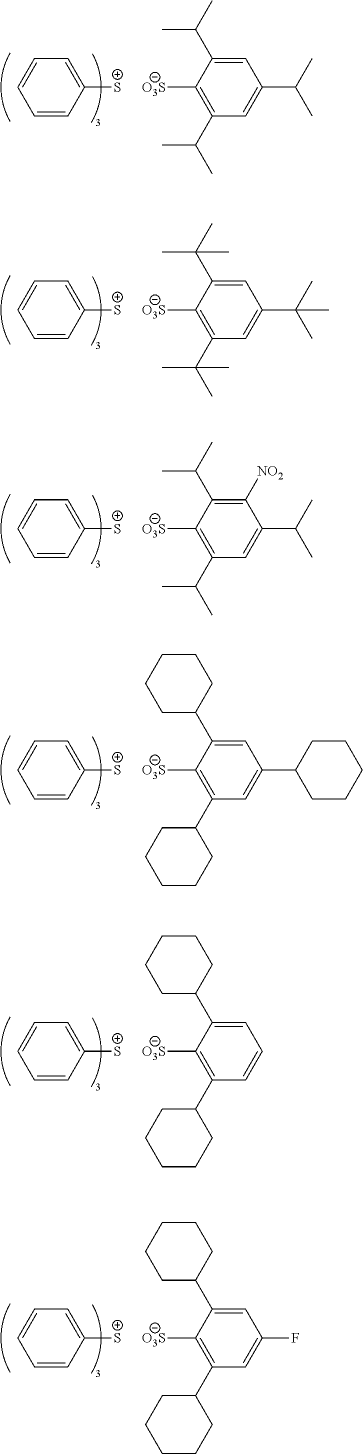

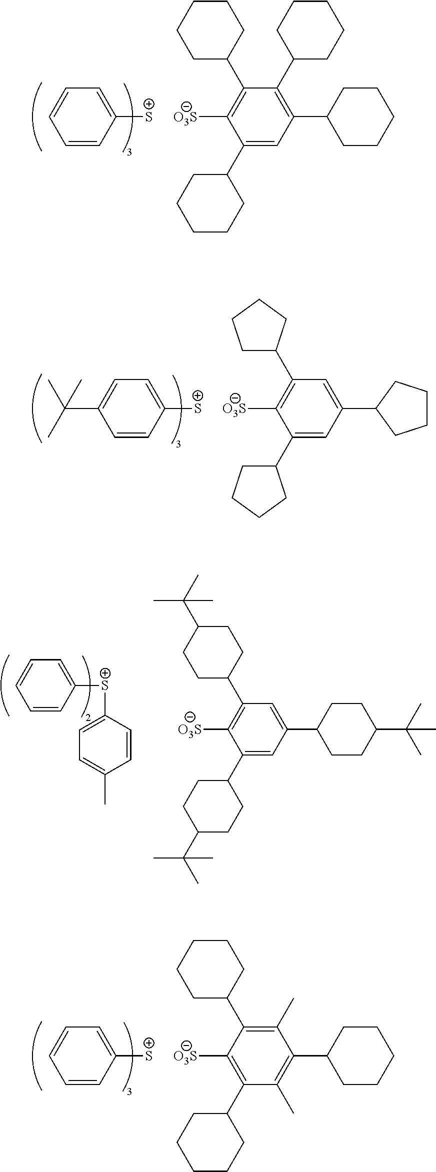

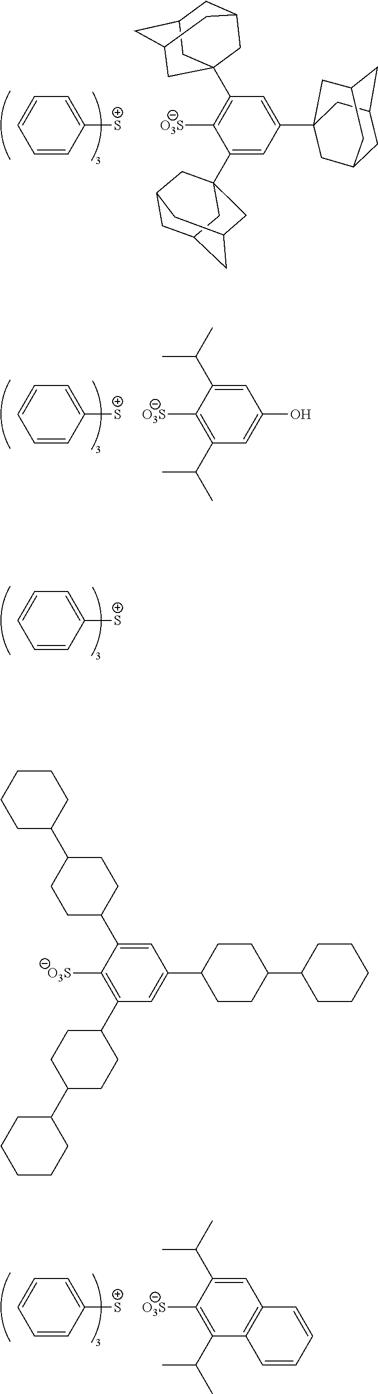

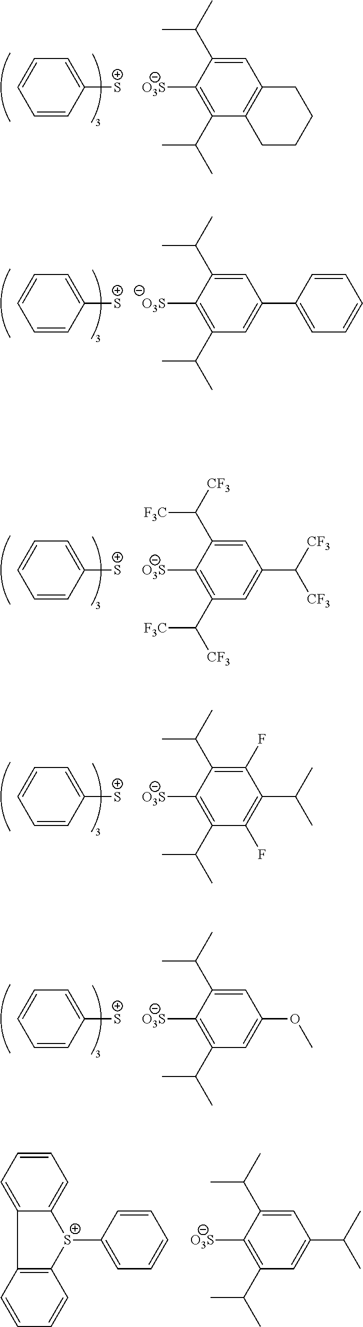

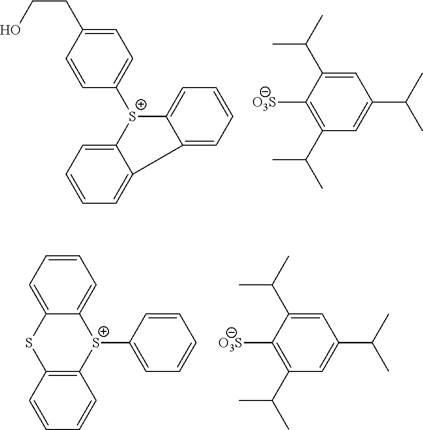

Two or more types of compounds that generate the acids of general formula (BIV) may be simultaneously used in the present invention.

The content of compounds that generate the acids of general formula (BIV) in the composition of the present invention based on the total solids thereof is preferably in the range of 0.1 to 20 mass %, more preferably 1 to 18 mass % and further more preferably 5 to 15 mass %.

In a further aspect, the actinic-ray- or radiation-sensitive resin composition according to the present invention contains, as the acid generator, a compound that generates any of the acids of general formulae (BII) and (BIII) below.

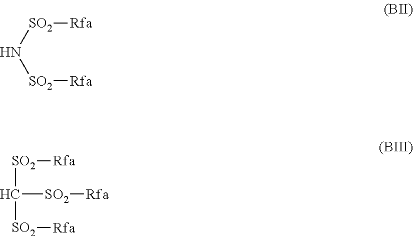

In general formulae (BII) and (BIII),

each of Rfas independently represents a monovalent organic group containing a fluorine atom, provided that the plurality of Rfas may be bonded to each other to thereby form a ring.

As the monovalent organic group containing a fluorine atom represented by Rfa, there can be mentioned a fluorinated alkyl group, a fluorinated cycloalkyl group, a fluorinated aryl group or the like.

As the fluorinated alkyl group, there can be mentioned, for example, a group as obtained by substituting at least one hydrogen atom of a linear or branched alkyl group having 1 to 8 carbon atoms, such as methyl, ethyl, propyl, isopropyl or octyl, with a fluorine atom. An oxygen atom or a sulfur atom may be introduced in each of these organic groups.

A substituent other than the fluorine atom may be introduced in the fluorinated alkyl group represented by Rfa. As preferred other substituents, there can be mentioned an alkoxy group, an iodine atom and the like.

In the fluorinated alkyl group, the fluorine atom is preferably bonded to the carbon atom bonded to the —SO₂— moiety. Further preferably, the fluorinated alkyl group is a linear or branched perfluoroalkyl group having 1 to 8 carbon atoms, such as a perfluoromethyl group, a perfluoroethyl group, a perfluoropropyl group, a perfluoroisopropyl group or a perfluorooctyl group. These enhance the solubility in solvents.

As the fluorinated cycloalkyl group represented by Rfa, there can be mentioned a cycloalkyl group entirely or partially substituted with a fluorine atom, in which further another substituent may be introduced. Fluorinated cyclopentyl and cyclohexyl groups are preferred. Perfluorocyclopentyl and perfluorocyclohexyl groups are most referred.

As the fluorinated aryl group represented by Rfa, there can be mentioned an aryl group entirely or partially substituted with a fluorine atom, in which further another substituent may be introduced. Fluorinated phenyl and naphthyl groups are preferred. A perfluorophenyl group is most referred.

The plurality of Rfas may be identical to or different from each other and may be bonded to each other to thereby form a ring. The ring formation enhances the stability thereof and enhances the storage stability of the composition using the same. When a ring is formed, it is preferred for the group formed by the bonding of the plurality of Rfas to be an alkylene group. This alkylene group preferably has 2 or 3 carbon atoms, and it is preferred for all the hydrogen atoms thereof to be fluorinated.

As preferred compounds that generate the acids of general formulae (BII) and (BIII), there can be mentioned those of the structures of general formulae (ZI″) and (ZII″) below.

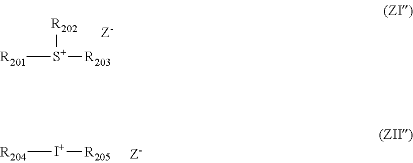

In general formula (ZI″),

each of R₂₀₁, R₂₀₂ and R₂₀₃ independently represents an organic group.

Z⁻ represents an anion as obtained by removing a hydrogen atom from the acids of general formulae (BII) and (BIII).

In general formula (ZII″),

each of R₂₀₄ and R₂₀₅ independently represents an aryl group, an alkyl group or a cycloalkyl group.

Z⁻ represents an anion as obtained by removing a hydrogen atom from the acids of general formulae (BII) and (BIII).

In general formula (ZI″), the number of carbon atoms of each of the organic groups represented by R₂₀₁, R₂₀₂ and R₂₀₃ is generally in the range of 1 to 30, preferably 1 to 20.

Two of R₂₀₁ to R₂₀₃ may be bonded to each other to thereby form a ring structure, and the ring within the same may contain an oxygen atom, a sulfur atom, an ester bond, an amido bond or a carbonyl group.

As the group formed by the bonding of two of R₂₀₁ to R₂₀₃, there can be mentioned an alkylene group (for example, a butylene group or a pentylene group).

As particular examples of the organic groups represented by R₂₀₁ to R₂₀₃, there can be mentioned corresponding groups of the structures (ZIa), (ZIb) and (ZIc) to be described hereinafter.

The acid generator may have two or more of the structures of general formula (ZI″). For example, the acid generator may have a structure wherein at least one of R₂₀₁ to R₂₀₃ of one of the structures of general formula (ZI″) is bonded to at least one of R₂₀₁ to R₂₀₃ of another of the structures of general formula (ZI″).

As further preferred (ZI″) structures, there can be mentioned the following structures (ZIa), (ZIb) and (ZIc).

The structures (ZIa) are arylsulfonium structures of general formula (ZI″) wherein at least one of R₂₀₁ to R₂₀₃ is an aryl group, namely, structures containing an arylsulfonium as a cation.

In the arylsulfonium structures, all of the R₂₀₁ to R₂₀₃ may be aryl groups. Alternatively, the R₂₀₁ to R₂₀₃ may be an aryl group in part and an alkyl group or a cycloalkyl group in the remainder.

As the arylsulfonium structures, there can be mentioned, for example, a triarylsulfonium structure, a diarylalkylsulfonium structure, a diarylcycloalkylsulfonium structure, an aryldialkylsulfonium structure, an aryldicycloalkylsulfonium structure, an arylalkylcycloalkylsulfonium structure and the like.

The aryl group of the arylsulfonium structures is preferably a phenyl group or a naphthyl group, more preferably a phenyl group. When any of the arylsulfonium structures contains two or more aryl groups, the two or more aryl groups may be identical to or different from each other.

The alkyl group contained in the arylsulfonium structures according to necessity is preferably a linear or branched alkyl group having 1 to 15 carbon atoms. As such, there can be mentioned, for example, a methyl group, an ethyl group, a propyl group, an n-butyl group, a sec-butyl group, a t-butyl group or the like.

The cycloalkyl group contained in the arylsulfonium structures according to necessity is preferably a cycloalkyl group having 3 to 15 carbon atoms. As such, there can be mentioned, for example, a cyclopropyl group, a cyclobutyl group, a cyclohexyl group or the like.

The aryl group, alkyl group or cycloalkyl group represented by R₂₀₁ to R₂₀₃ may have as a substituent thereof an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxyl group or a phenylthio group. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. An alkyl group having 1 to 4 carbon atoms and an alkoxy group having 1 to 4 carbon atoms are most preferred. The substituents may be introduced in any one of the three R₂₀₁ to R₂₀₃, or alternatively may be introduced in all of the three R₂₀₁ to R₂₀₃. When R₂₀₁ to R₂₀₃ represent aryl groups, the substituent is preferably introduced in the p-position of the aryl group.

Now, the structures (ZIb) will be described.

The structures (ZIb) are structures of general formula (ZI″) wherein each of R₂₀₁ to R₂₀₃ independently represents an organic group having none of aromatic rings. The aromatic rings include an aromatic ring containing a heteroatom.

Each of the organic groups having no aromatic ring represented by R₂₀₁ to R₂₀₃ generally has 1 to 30 carbon atoms, preferably 1 to 20 carbon atoms.

Each of the organic groups having no aromatic ring represented by R₂₀₁ to R₂₀₃ is preferably an alkyl group, a cycloalkyl group, an allyl group or a vinyl group. A linear, branched or cyclic oxoalkyl group and an alkoxycarbonylmethyl group each optionally having a double bond in the chain thereof are more preferred. A linear, branched or cyclic 2-oxoalkyl group is further more preferred. Especially preferred is a linear or branched 2-oxoalkyl group.

The alkyl groups represented by R₂₀₁ to R₂₀₃ may be linear or branched, being preferably a linear or branched alkyl group having 1 to 20 carbon atoms (for example, a methyl group, an ethyl group, a propyl group, a butyl group or a pentyl group). It is especially preferred for each of the alkyl groups represented by R₂₀₁ to R₂₀₃ to be a linear or branched oxoalkyl group or alkoxycarbonylmethyl group.

As preferred cycloalkyl groups represented by R₂₀₁ to R₂₀₃, there can be mentioned a cycloalkyl group having 3 to 10 carbon atoms (a cyclopentyl group, a cyclohexyl group or a norbornyl group).

Each of the cycloalkyl groups represented by R₂₀₁ to R₂₀₃ is preferably a cyclic oxoalkyl group.

Each of the oxoalkyl groups represented by R₂₀₁ to R₂₀₃ may be linear, branched or cyclic. As preferred examples, there can be mentioned groups consisting of any of the above alkyl and cycloalkyl groups having >C═O at the 2-position thereof.

As preferred alkoxy groups of the alkoxycarbonylmethyl groups represented by R₂₀₁ to R₂₀₃, there can be mentioned alkoxy groups having 1 to 5 carbon atoms (a methoxy group, an ethoxy group, a propoxy group, a butoxy group and a pentoxy group).

These R₂₀₁ to R₂₀₃ may be further substituted with a halogen atom, an alkoxy group (for example, 1 to 5 carbon atoms), a hydroxyl group, a cyano group or a nitro group.

The structures (ZIc) are those of general formula (ZIc) below, being arylacylsulfonium salt structures.

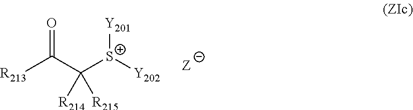

In general formula (ZIc),

R₂₁₃ represents an aryl group, being preferably a phenyl group or a naphthyl group. A substituent may be introduced in the aryl group represented by R₂₁₃. As the substituent that may be introduced in the aryl group represented by R₂₁₃, there can be mentioned, for example, an alkyl group, an alkoxy group, an acyl group or the like.

Each of R₂₁₄ and R₂₁₅ independently represents a hydrogen atom, an alkyl group or a cycloalkyl group.

Each of Y₂₀₁ and Y₂₀₂ independently represents an alkyl group, a cycloalkyl group, an aryl group or a vinyl group.

R₂₁₃ and R₂₁₄ may be bonded to each other to thereby form a ring structure. R₂₁₄ and R₂₁₅ may be bonded to each other to thereby form a ring structure. Y₂₀₁ and Y₂₀₂ may be bonded to each other to thereby form a ring structure. Each of these ring structures may contain an oxygen atom, a sulfur atom, an ester bond or an amido bond.

Z⁻ represents an anion as obtained by removing a hydrogen atom from the acids of general formulae (BI) and (BII).

Each of the alkyl groups represented by R₂₁₄ and R₂₁₅ is preferably a linear or branched alkyl group having 1 to 20 carbon atoms.

Each of the cycloalkyl groups represented by R₂₁₄ and R₂₁₅ is preferably a cycloalkyl group having 3 to 20 carbon atoms.

Each of the alkyl groups represented by Y₂₀₁ and Y₂₀₂ is preferably a linear or branched alkyl group having 1 to 20 carbon atoms. A 2-oxoalkyl group consisting of any of the above alkyl groups having >C═O at the 2-position thereof, an alkoxycarbonylalkyl group (preferably an alkoxy group having 2 to 20 carbon atoms) and a carboxyalkyl group are more preferred.

Each of the cycloalkyl groups represented by Y₂₀₁ and Y₂₀₂ is preferably a cycloalkyl group having 3 to 20 carbon atoms.

Each of the aryl groups represented by Y₂₀₁ and Y₂₀₂ is preferably an aryl group having 6 to 20 carbon atoms.

As groups formed by the mutual bonding of R₂₁₃ and R₂₁₄, or R₂₁₄ and R₂₁₅, or Y₂₀₁ and Y₂₀₂, there can be mentioned a butylene group, a pentylene group and the like.

Y₂₀₁ and Y₂₀₂ are preferably alkyl groups each having 4 to 16 carbon atoms, more preferably 4 to 12 carbon atoms.

It is preferred for at least one of R₂₁₄ and R₂₁₅ to be an alkyl group. It is more preferred for both of R₂₁₄ and R₂₁₅ to be alkyl groups.

Each of the aryl groups represented by R₂₀₄ and R₂₀₅ in general formula (ZII″) is preferably a phenyl group or a naphthyl group, more preferably a phenyl group.

Z⁻ represents an anion as obtained by removing a hydrogen atom from the acids of general formulae (BII) and (BIII).

Each of the alkyl groups represented by R₂₀₄ and R₂₀₅ may be linear or branched, being preferably a linear or branched alkyl group having 1 to 10 carbon atoms (for example, a methyl group, an ethyl group, a propyl group, a butyl group or a pentyl group).

Each of the cycloalkyl groups represented by R₂₀₄ and R₂₀₅ is preferably a cycloalkyl group having 3 to 10 carbon atoms (a cyclopentyl group, a cyclohexyl group or a norbornyl group).

R₂₀₄ and R₂₀₅ may have substituents. As the substituents that may be introduced in R₂₀₄ and R₂₀₅, there can be mentioned, for example, an alkyl group (for example, 1 to 15 carbon atoms), a cycloalkyl group (for example, 3 to 15 carbon atoms), an aryl group (for example, 6 to 15 carbon atoms), an alkoxy group (for example, 1 to 15 carbon atoms), a halogen atom, a hydroxyl group, a phenylthio group and the like.

The cation structure is preferably any of the structures of general formula (ZI″), more preferably any of the structures of general formulae (ZIa) to (ZIc).

Specific examples of the compounds (B) that when exposed to actinic rays or radiation, generate the acids of general formulae (BII) and (BIII) will be shown below, which in no way limit the scope of the present invention.

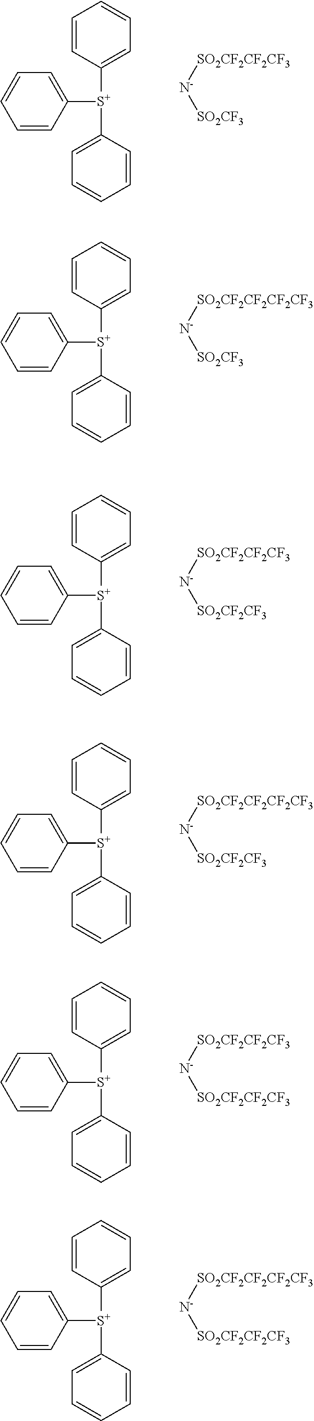

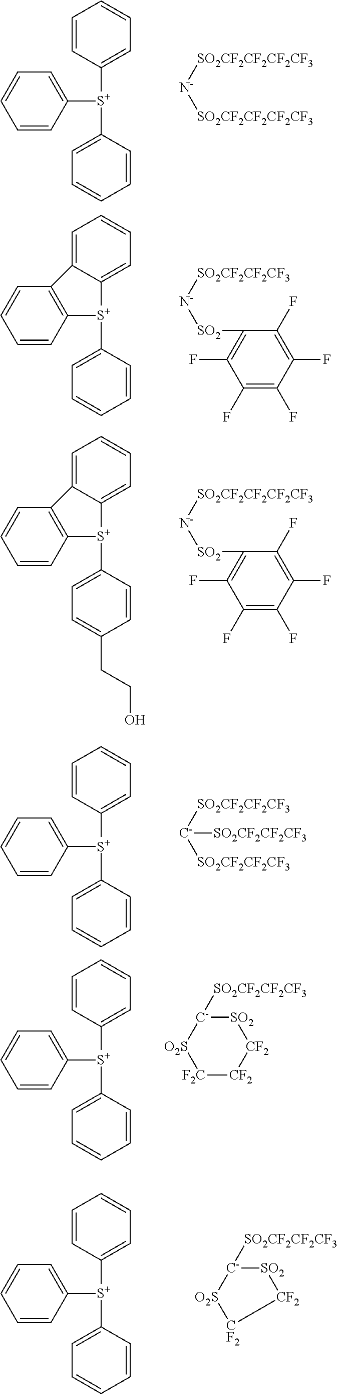

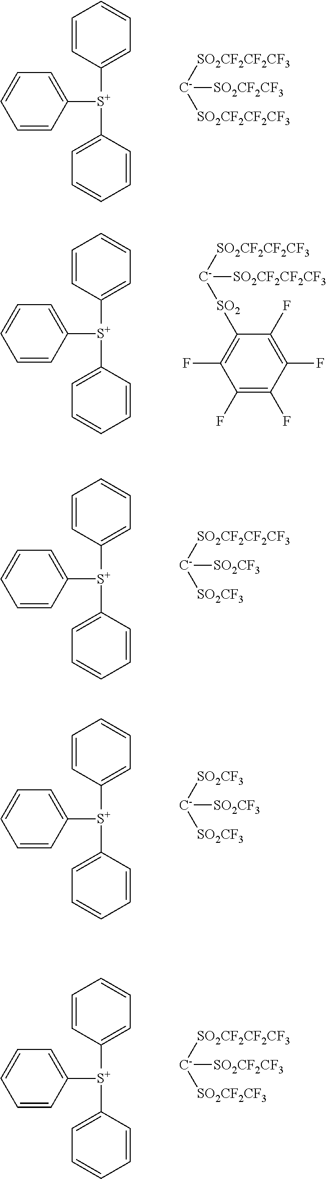

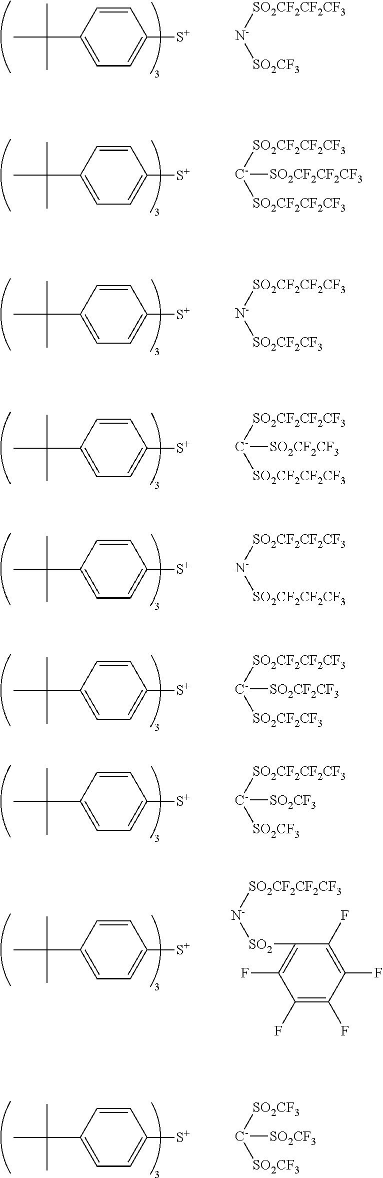

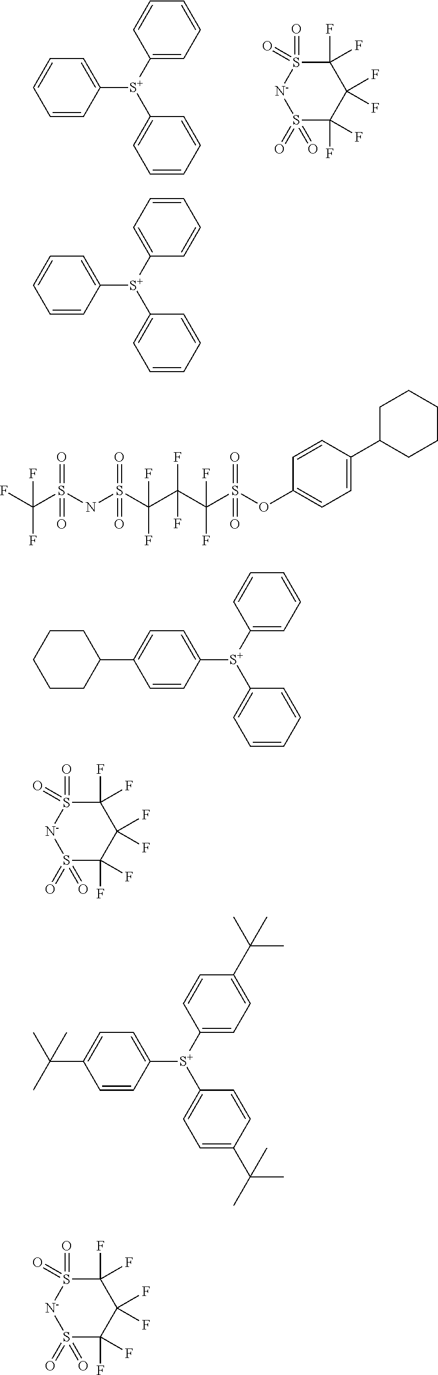

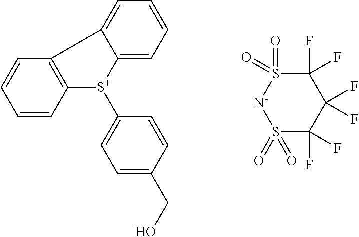

The acid compound and lithium, sodium or potassium salt of the anion component of any of the compounds of general formulae (BII) and (BIII) can be easily synthesized in accordance with the procedure described in U.S. Pat. No. 5,554,664. Some thereof are available from, for example, SynQuest Laboratories, Hydrus Chemical Inc. or AZmax Co., Ltd.

The compounds (B) can be easily synthesized from the acid compound or lithium, sodium or potassium salt of the anion component of any of the compounds of general formulae (BII) and (BIII) and, for example, the hydroxide, bromide and chloride of an iodonium cation or a sulfonium cation by the use of the salt exchange method described in Jpn. PCT National Publication No. 11-501909 and JP-A's 2003-246786, 2004-26789 and 2004-12554.

The content of compounds that generate the acids of general formulae (BII) and (BIII) in the composition of the present invention based on the total solids thereof is preferably in the range of 1 to 20 mass %, more preferably 2 to 18 mass % and further more preferably 5 to 15 mass %. The compounds (B) can be used individually or in combination.

Moreover, in the present invention, acid generators other than the above acid generators can be used in combination with the above acid generators. As such other acid generators, there can be mentioned, for example, the alkylsulfonate anions, arylsulfonate anions, bis(alkylsulfonyl)imide anions and tris(alkylsulfonyl)methide anions of general formulae (ZI) and (ZII) wherein Z⁻ does not fall within the anion structures of general formulae (BI) to (BVI). The alkyl and aryl groups of these anions may be substituted with a fluorine atom or the like. As particular examples of such acid generators, there can be mentioned those set forth in section [0150] of US. Patent Application Publication No. 2008/0248425.

### [3] Organic Basic Compound (C)

The composition of the present invention may comprise a basic compound. The basic compound is preferably a nitrogenous organic basic compound. Useful basic compounds are not particularly limited. However, for example, the compounds of categories (1) to (4) below are preferably used.

(1) Compounds of General Formula (BS-1) Below

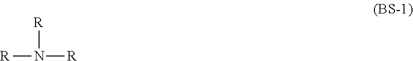

In General Formula (BS-1), each of Rs independently represents any of a hydrogen atom, an alkyl group (linear or branched), a cycloalkyl group (monocyclic or polycyclic), an aryl group and an aralkyl group, provided that in no event all the three Rs are hydrogen atoms.

The number of carbon atoms of the alkyl group represented by R is not particularly limited. However, it is generally in the range of 1 to 20, preferably 1 to 12.

The number of carbon atoms of the cycloalkyl group represented by R is not particularly limited. However, it is generally in the range of 3 to 20, preferably 5 to 15.

The number of carbon atoms of the aryl group represented by R is not particularly limited. However, it is generally in the range of 6 to 20, preferably 6 to 10. In particular, a phenyl group, a naphthyl group and the like can be mentioned.

The number of carbon atoms of the aralkyl group represented by R is not particularly limited. However, it is generally in the range of 7 to 20, preferably 7 to 11. In particular, a benzyl group and the like can be mentioned.

In the alkyl group, cycloalkyl group, aryl group and aralkyl group represented by R, a hydrogen atom thereof may be replaced by a substituent. As the substituent, there can be mentioned, for example, an alkyl group, a cycloalkyl group, an aryl group, an aralkyl group, a hydroxyl group, a carboxyl group, an alkoxy group, an aryloxy group, an alkylcarbonyloxy group, an alkyloxycarbonyl group or the like.

In the compounds of General Formula (BS-1), it is preferred that only one of the three Rs be a hydrogen atom, and also that none of the Rs be a hydrogen atom.

Specific examples of the compounds of General Formula (BS-1) include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline and the like.

Any of the compounds of General Formula (BS-1) in which at least one of the Rs is a hydroxylated alkyl group can be mentioned as a preferred form of compound. Specific examples of the compounds include triethanolamine, N,N-dihydroxyethylaniline and the like.

With respect to the alkyl group represented by R, an oxygen atom may be present in the alkyl chain to thereby form an oxyalkylene chain. The oxyalkylene chain preferably consists of —CH₂CH₂O—. As particular examples thereof, there can be mentioned tris(methoxyethoxyethyl)amine, compounds shown in column 3 line 60 et seq. of U.S. Pat. No. 6,040,112 and the like.

(2) Compounds with Nitrogenous Heterocyclic Structure

The heterocyclic structure optionally may have aromaticity. It may have a plurality of nitrogen atoms, and also may have a heteroatom other than nitrogen. For example, there can be mentioned compounds with an imidazole structure (2-phenylbenzoimidazole, 2,4,5-triphenylimidazole and the like), compounds with a piperidine structure (N-hydroxyethylpiperidine, bis(1,2,2,6,6-pentamethyl-4-piperidyl) sebacate and the like), compounds with a pyridine structure (4-dimethylaminopyridine and the like) and compounds with an antipyrine structure (antipyrine, hydroxyantipyrine and the like).

Further, compounds with two or more ring structures can be appropriately used. For example, there can be mentioned 1,5-diazabicyclo[4.3.0]non-5-ene, 1,8-diazabicyclo[5.4.0]-undec-7-ene and the like.

(3) Amine Compounds with Phenoxy Group

The amine compounds with a phenoxy group are those having a phenoxy group at the end of the alkyl group of each amine compound opposite to the nitrogen atom. The phenoxy group may have a substituent, such as an alkyl group, an alkoxy group, a halogen atom, a cyano group, a nitro group, a carboxyl group, a carboxylic ester group, a sulfonic ester group, an aryl group, an aralkyl group, an acyloxy group, an aryloxy group or the like.

Compounds having at least one oxyalkylene chain between the phenoxy group and the nitrogen atom are preferred. The number of oxyalkylene chains in each molecule is preferably in the range of 3 to 9, more preferably 4 to 6. Among the oxyalkylene chains, —CH₂CH₂O— is preferred.

Particular examples thereof include 2-[2-{2-(2,2-dimethoxy-phenoxyethoxy)ethyl}-bis-(2-methoxyethyl)]-amine, compounds (C1-1) to (C3-3) shown in section [0066] of US 2007/0224539 A1 and the like.

(4) Ammonium Salts Derived from any of the Above Compounds (1) to (3)

Ammonium salts can also be appropriately used. Hydroxides and carboxylates are preferred. Preferred particular examples thereof are tetraalkylammonium hydroxides, such as tetrabutylammonium hydroxide.

Also, use can be made of compounds synthesized in Examples of JP-A-2002-363146, compounds described in section [0108] of JP-A-2007-298569, and the like.

These basic compounds are used alone or in combination.

The amount of basic compound added is generally in the range of 0.001 to 10 mass %, preferably 0.01 to mass %, based on the total solid of the composition.

The molar ratio of acid generator to basic compound is preferably in the range of 2.5 to 300. A molar ratio of 2.5 or higher is preferred from the viewpoint of sensitivity and resolving power. A molar ratio of 300 or below is preferred from the viewpoint of suppressing any resolving power drop due to pattern thickening over time until baking treatment after exposure. The molar ratio is more preferably in the range of 5.0 to 200, further more preferably 7.0 to 150.

### [4] Solvent

The solvent for use in the preparation of the composition is not particularly limited as long as it can dissolve the components of the composition. As the solvent, there can be mentioned, for example, an alkylene glycol monoalkyl ether carboxylate (propylene glycol monomethyl ether acetate or the like), an alkylene glycol monoalkyl ether (propylene glycol monomethyl ether or the like), an alkyl lactate (ethyl lactate, methyl lactate or the like), a cyclolactone (γ-butyrolactone or the like, preferably having 4 to 10 carbon atoms), a linear or cyclic ketone (2-heptanone, cyclohexanone or the like, preferably having 4 to 10 carbon atoms), an alkylene carbonate (ethylene carbonate, propylene carbonate or the like), an alkyl carboxylate (preferably an alkyl acetate such as butyl acetate), an alkyl alkoxyacetate (ethyl ethoxypropionate), or the like. As other useful solvents, there can be mentioned, for example, those described in section [0244] et seq. of US 2008/0248425 A1 and the like.

Among the above solvents, an alkylene glycol monoalkyl ether carboxylate, an alkylene glycol monoalkyl ether and an alkyl lactate are preferred.

These solvents may be used alone or in combination. When a plurality of solvents are mixed together, it is preferred to mix a hydroxylated solvent with a non-hydroxylated solvent. The mass ratio of hydroxylated solvent to non-hydroxylated solvent is in the range of 1/99 to 99/1, preferably 10/90 to 90/10 and more preferably 20/80 to 60/40.

The hydroxylated solvent is preferably an alkylene glycol monoalkyl ether and an alkyl lactate. The non-hydroxylated solvent is preferably an alkylene glycol monoalkyl ether carboxylate.

The amount of solvent used can be appropriately regulated in accordance with, for example, the film thickness at application. It is generally appropriate to use the solvent so that the total solid content of the composition falls within the range of 0.5 to 20 mass %, preferably 1.0 to 25 mass % and more preferably 1.5 to 20 mass %.

### [5] Surfactant

Preferably, the composition of the present invention further contains a surfactant. The surfactant is preferably a fluorinated and/or siliconized surfactant.

As such a surfactant, there can be mentioned Megafac F176 or Megafac R08 produced by Dainippon Ink & Chemicals, Inc., PF656 or PF6320 produced by OMNOVA SOLUTIONS, INC., Troy Sol S-366 produced by Troy Chemical Co., Ltd., Florad FC430 produced by Sumitomo 3M Ltd., polysiloxane polymer KP-341 produced by Shin-Etsu Chemical Co., Ltd., or the like.

Surfactants other than these fluorinated and/or siliconized surfactants can also be used. In particular; the other surfactants include polyoxyethylene alkyl ethers, polyoxyethylene alkyl aryl ethers and the like.

Moreover, generally known surfactants can also be appropriately used. As useful surfactants, there can be mentioned, for example, those described in section [0273] et seq of US 2008/0248425 A1.

It is especially preferred for the surfactant for use in the present invention to be any of those having the structures of formula (II) below.

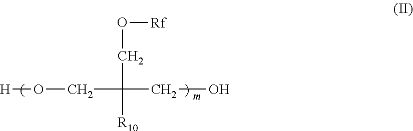

In general formula (II),

R₁₀ represents a hydrogen atom or an alkyl group.

Rf represents a fluoroalkyl group or a fluoroalkylcarbonyl group, and

m is an integer of 1 to 50.

An oxygen atom and a double bond may be introduced in the alkyl chain of the fluoroalkyl group represented by Rf in general formula (II). As the fluoroalkyl group, there can be mentioned, for example, —CF₃, —C₂F₅, —C₄F₉, —CH₂CF₃, —CH₂C₂F₅, —CH₂C₃F₇, —CH₂C₄F₉, —CH₂C₆F₁₃, —C₂H₄CF₃, —C₂H₄C₂F₅, —C₂H₄C₄F₉, —C₂H₄C₆F₁₃, —C₂H₄C₈F₁₇, —CH₂CH(CH₃)CF₃, —CH₂CH(CF₃)₂, —CH₂CF(CF₃)₂, —CH₂CH(CF₃)₂, —CF₂CF(CF₃)OCF₃, —CF₂CF(CF₃)OC₃F₇, —C₂H₄OCF₂CF(CF₃)OCF₃, —C₂H₄OCF₂CF(CF₃)OC₃F₇, —C(CF₃)═C(CF(CF₃)₂)₂ or the like.

As the fluoroalkylcarbonyl group represented by Rf, there can be mentioned, for example, —COCF₃, —COC₂F₅, —COC₃F₇, —COC₄F₉, —COC₆F₁₃, —COC₈F₁₇ or the like.

The alkyl group represented by R₁₀ preferably has 1 to 10 carbon atoms, more preferably 1 to 5 carbon atoms.

Particular examples of the surfactants of the above general formula (II) will be shown below, which in no way limit the scope of the surfactants.

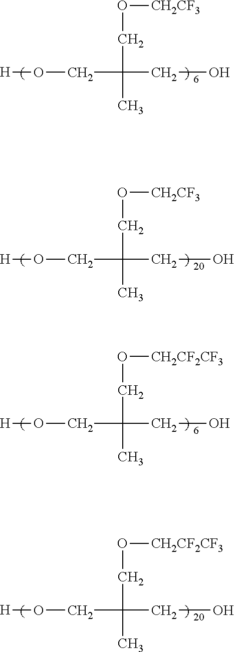

These surfactants may be used alone or in combination.

The amount of surfactant added is preferably in the range of 0.0001 to 2 mass %, more preferably 0.001 to 1 mass %, based on the total solid of the composition.

The ratio of surfactants of the formula (II) to other surfactants used in terms of mass ratio (surfactants of the formula (II)/other surfactants) is preferably in the range of 60/40 to 99/1, more preferably 70/30 to 99/1.

### [6] Other Components

In addition to the above components, an onium salt of carboxylic acid, any of the dissolution inhibiting compounds of 3000 or less molecular weight described in, for example, Proceeding of SPIE, 2724,355 (1996), a dye, a plasticizer, a photosensitizer, a light absorber, an antioxidant, etc. can be appropriately incorporated in the composition of the present invention.

<Method of Forming Pattern>

The mode of usage of the actinic-ray- or radiation-sensitive resin composition of the present invention will now be described.

The method of forming a pattern according to the present invention comprises the step (1) of forming the actinic-ray- or radiation-sensitive resin composition into a film, the step (2) of exposing the film to light and the step (4) of developing the exposed film with the use of an alkali developer. The method may further comprise the step (3) of baking (heating) to be performed between the exposure step (2) and the development step (4).

(1) Film Formation

The film of the actinic-ray- or radiation-sensitive resin composition of the present invention is obtained by dissolving appropriate components in a solvent, optionally filtering the solution and applying the same onto a support (substrate). The filter medium for the filtration preferably consists of a polytetrafluoroethylene, polyethylene or nylon having a pore size of 0.1 μm or less, more preferably 0.05 μm or less and further more preferably 0.03 μm or less.

The composition is applied onto a substrate, such as one for use in the production of integrated circuit elements (e.g., silicon/silicon dioxide coating), by appropriate application means, such as a spinner, and thereafter dried to thereby obtain a photosensitive film.

According to necessity, a commercially available inorganic or organic antireflection film can be applied. The antireflection film can be used by applying the same to a resist sublayer.

(2) Exposure

The film obtained by the above film forming step is exposed generally through a given mask to actinic rays or radiation. In the present invention, electron beams or EUV light is preferably used as the actinic rays or radiation. In the exposure using electron beams, lithography through no mask (direct lithography) is generally carried out.

(3) Bake

It is preferred to perform baking (heating) after the exposure but before development.

The heating temperature is preferably in the range of 80° to 150° C., more preferably 90° to 150° C. and further more preferably 100° to 140° C.

The heating time is preferably in the range of 30 to 300 seconds, more preferably 30 to 180 seconds and further more preferably 30 to 90 seconds.

The heating can be carried out by means provided in a conventional exposure/development system and may also be carried out using a hot plate or the like.

The bake accelerates the reaction in exposed areas, thereby enhancing the sensitivity and pattern profile.

(4) Alkali Development

As the alkali developer, use can be made of an aqueous solution (generally 0.1 to 20 mass %) of an alkali selected from among an inorganic alkali such as sodium hydroxide, potassium hydroxide, sodium carbonate, sodium silicate, sodium metasilicate or aqueous ammonia, a primary amine such as ethylamine or n-propylamine, a secondary amine such as diethylamine or di-n-butylamine, a tertiary amine such as triethylamine or methyldiethylamine, an alcoholamine such as dimethylethanolamine or triethanolamine, a quaternary ammonium salt such as tetramethylammonium hydroxide, tetraethylammonium hydroxide or choline, a cycloamine such as pyrrole or piperidine, and the like. Before the use of the above alkali aqueous solutions, appropriate amounts of an alcohol, such as isopropyl alcohol, and a surfactant, such as a nonionic surfactant, can be added thereto.

In these developers, a quaternary ammonium salt is preferably used, and tetramethylammonium hydroxide or choline is more preferably used.

The pH value of the alkali developer is generally in the range of 10 to 15.

As the development method, use can be made of, for example, any of a method in which the substrate is dipped in a tank filled with a developer for a given period of time (dip method), a method in which a developer is mounded on the surface of the substrate by its surface tension and allowed to stand still for a given period of time to thereby effect development (puddle method), a method in which a developer is sprayed onto the surface of the substrate (spray method), a method in which a developer is continuously applied onto the substrate rotating at a given speed while scanning a developer application nozzle at a given speed (dynamic dispense method), and the like.

The development step may be followed by the step of discontinuing the development by replacing the developer with pure water.

The development time is preferably enough to satisfactorily dissolve any resins, crosslinking agents, etc. remaining in unexposed areas. Generally, the development time of 10 to 300 seconds is preferred, and the development time of 20 to 120 seconds is more preferred.

The temperature of the developer is preferably in the range of 0° to 50° C., more preferably 15° to 35° C.

### EXAMPLE

### (1) Synthetic Example

### Synthetic Example 1

### Synthesis of Polymer (P-1)

Ethylene glycol monoethyl ether acetate amounting to 600 g was placed in a 2-liter flask, and flushed with nitrogen flowing at a rate of 100 ml/min for an hour. Separately, 105.4 g (0.65 mol) of 4-acetoxystyrene, 63.8 g (0.35 mol) of 1-ethylcyclopentyl methacrylate and 4.60 g (0.02 mol) of polymerization initiator V-601 (produced by Wako Pure Chemical Industries, Ltd.) were dissolved in 200 g of ethylene glycol monoethyl ether acetate, and the thus obtained monomer mixture solution was flushed with nitrogen in the same manner as above.

The 2-liter flask charged with ethylene glycol monoethyl ether acetate was heated until the internal temperature became 80° C., and 2.30 g (0.01 mol) of polymerization initiator V-601 was added to the ethylene glycol monoethyl ether acetate and agitated for 5 minutes. Thereafter, the above monomer mixture solution was dropped thereinto under agitation over a period of 6 hours. After the completion of the dropping, heating and agitation were continued for 2 hours. The thus obtained reaction solution was cooled to room temperature, and dropped into 3 liters of hexane to thereby precipitate a polymer. The solid recovered by filtration was dissolved in 500 ml of acetone and dropped once more into 3 liters of hexane. The solid recovered by filtration was dried in vacuum, thereby obtaining 145 g of 4-acetoxystyrene/1-ethylcyclopentyl methacrylate copolymer.

The obtained copolymer amounting to 40.00 g together with 40 ml of methanol, 200 ml of 1-methoxy-2-propanol and 1.5 ml of concentrated hydrochloric acid was placed in a reaction vessel, heated to 80° C. and agitated for 5 hours. The resultant reaction solution was allowed to cool to room temperature and dropped into 3 liters of distilled water. The solid recovered by filtration was dissolved in 200 ml of acetone, and dropped once more into 3 liters of distilled water. The solid recovered by filtration was dried in vacuum, thereby obtaining 35.5 g of polymer (P-1). The weight average molecular weight and dispersity of molecular weight (Mw/Mn) of the polymer as measured by GPC were 10,800 and 1.65, respectively.

The resins (P-2) to (P-8b) with the structures shown below were synthesized in the same manner as in Synthetic Example 1 except that the employed monomers were changed. With respect to each of the resins, the component ratio, weight average molecular weight (Mw) and dispersity of molecular weight (Mw/Mn) are given in Table 1. The component ratio (molar ratio) refers to the molar proportions of individual repeating units shown below of each of the resins in order from the left.

TABLE 1

| | | Comp. ratio | | |
|---|---|---|---|---|
| | | (mol %) | Mw | Mw/Mn |
| P-1 | | 65/35 | 10800 | 1.65 |
| P-2 | | 70/30 | 10500 | 1.58 |
| P-3 | | 60/30/10 | 11000 | 1.6 |
| P-4 | | 70/30 | 10200 | 1.61 |
| P-5 | | 80/20 | 9500 | 1.65 |
| P-6 | | 60/40 | 12000 | 1.7 |
| P-7 | | 75/25 | 11000 | 1.55 |
| P-8 | P-8a | 60/30/10 | 11000 | 1.6 |
| | P-8b | 70/20/10 | 11000 | 1.6 |
| P-9 | | 50/10/40 | 11000 | 1.6 |

| | |
|---|---|
| 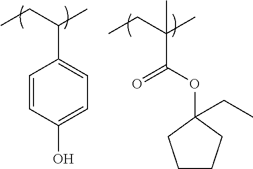 | P-1 |
| 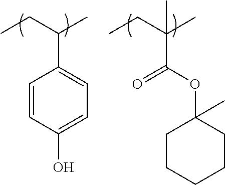 | P-2 |
| 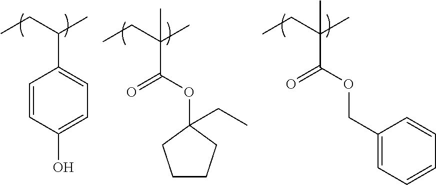 | P-3 |
| 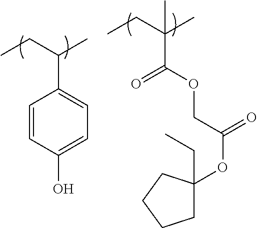 | P-4 |
| 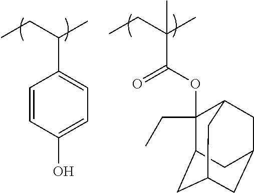 | P-5 |
| 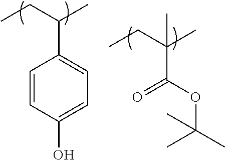 | P-6 |
| 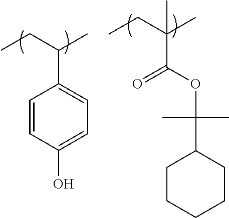 | P-7 |
| 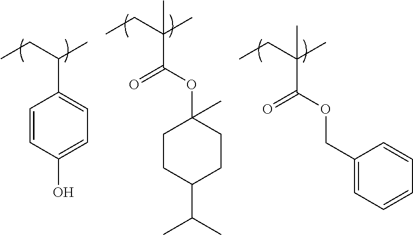 | P-8 |
| 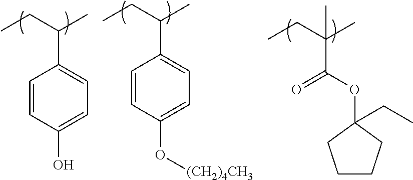 | P-9 |

### (2) EB Exposure Evaluation

### (2-1) Preparation of Resist Coating Liquid and Application Thereof

The coating liquid compositions with formulations given in Table 2 were prepared, and precision filtration thereof was performed using a membrane filter of 0.1 μm pore size, thereby obtaining resist solutions.

Each of the obtained resist solutions was applied onto a 6-inch Si wafer having undergone HMDS treatment by means of a spin coater Mark 8 manufactured by Tokyo Electron Limited, and dried by baking on a hot plate set at the temperature indicated in Table 3. Thus, resist films each having a thickness of 0.12 μm were obtained.

### (2-2) EB Exposure

Each of the resist films obtained in the step (2-1) above was patternwise exposed by means of an electron beam lithography system (HL750 manufactured by Hitachi, Ltd., acceleration voltage 50 KeV). The exposed resist film was baked on a hot plate set at the temperature indicated in Table 3.

The baked resist film was dipped in a 2.38 mass % aqueous tetramethylammonium hydroxide (TMAH) solution for 60 seconds, rinsed with water for 30 seconds and dried.

The thus obtained patterns were evaluated by the following methods. The evaluation results are given in Table 3 below.

### (2-3-1) Sensitivity (E₀)

Each of the obtained patterns was observed by means of a scanning electron microscope (model S-9220, manufactured by Hitachi, Ltd.). The sensitivity (E₀) was defined as the electron beam exposure amount at which 0.10 μm (line:space=1:1) was resolved.

### (2-3-2) Resolving Power (Dense)

The resolving power (dense) was defined as the limiting resolving power of 1:1 line space (minimum line width at which the line and space were separated and resolved from each other) at the exposure amount exhibiting the above sensitivity.

### (2-3-3) Resolving Power (Isolated)

Each of the patterns was observed by means of a scanning electron microscope (model S-9220, manufactured by Hitachi, Ltd.). The resolving power (isolated) was defined as the minimum line width for isolated line formation at the electron beam exposure amount at which a 0.1 μm pattern of isolated line (1:10 line space) was resolved.

### (2-3-4) Exposure Latitude (EL)

The exposure latitude was defined as the numeric value calculated by the following formula in which E₁ represented the sensitivity at which the pattern size was 0.09 μm and E₂ represented the sensitivity at which the pattern size was 0.11 μm.

Exposure latitude=(E₁−E₂)/E₀×100(%)

### (2-3-5) Line Width Roughness (LWR)

The line width was measured at arbitrary 30 points in a 50 μm region along the longitudinal direction of a 0.10 μm line pattern at the exposure amount exhibiting the above sensitivity. The data spread was evaluated by 3σ.

### (2-3-6) Stability Against Post-Exposure Time Delay in Vacuum (PED Stability)

In one instance, after the completion of patternwise exposure, the exposed film was allowed to stand still for 48 hours in the apparatus and processed for pattern formation. In another instance, after the completion of patternwise exposure, the exposed film was immediately taken out from the apparatus and processed for pattern formation in the same manner. The pattern size difference at the same exposure amount between the two instances was evaluated. The smaller the pattern size difference, the more favorable the in-vacuum PED stability performance.

### (2-3-7) Bridge Margin

The exposure amount E₀ (optimum exposure amount) for resolving the obtained 0.10 μm line-and-space resist pattern was determined using a scanning electron microscope (model S-9220, manufactured by Hitachi, Ltd.). Further, the exposure amount E₁ for bridging occurring when the exposure amount was reduced from the exposure amount E₀ was determined. These exposure amounts were introduced in formula 1 below, and the index of bridge margin was defined as the thus calculated numeric value.

Bridge margin (%)=[(E₀−E₁)/E₀]×100 (1)

The larger the thus calculated value, the more favorable the bridge margin performance.

### (2-3-8) Isolated Space Resolvability

Each 75 nm isolated space pattern was observed through a scanning electron microscope (model S-9220, manufactured by Hitachi, Ltd.). The isolated space resolvability was defined as the minimum space width that can be resolved.

TABLE 2

| | | | Organic | | |
|---|---|---|---|---|---|
| | (A) | (B) Acid | basic | | |
| | Resin | generator | compound | Surfactant | Solvent |
| | (mg) | (mg) | (mg) | (2.5 mg) | (g) |
| Ex. 1 | P-1 | B-1 | D-1 | W-1 | S-1 |
| | (840) | (150) | (8) | | (24) |
| Ex. 2 | P-2 | B-2 | D-2 | W-2 | S-1/S-2 |
| | (840) | (150) | (8) | | (18/6) |
| Ex. 3 | P-3 | B-3 | D-1/D-3 | W-3 | S-1/S-2 |
| | (840) | (150) | (4/4) | | (18/6) |
| Ex. 4 | P-1 | B-4 | D-2/D-4 | W-2 | S-1/S-2 |
| | (840) | (150) | (4/4) | | (18/6) |
| Ex. 5 | P-4 | B-1/B-13 | D-1 | W-4 | S-1/S-3 |
| | (850) | (90/50) | (8) | | (18/6) |
| Ex. 6 | P-3 | B-1/B-3 | D-1 | W-5 | S-1/S-4 |
| | (840) | (75/75) | (8) | | (18/6) |
| Ex. 7 | P-1 | B-5 | D-1 | W-1 | S-1 |
| | (890) | (100) | (8) | | (24) |
| Ex. 8 | P-2 | B-6 | D-2 | W-2 | S-1/S-2 |
| | (840) | (150) | (8) | | (18/6) |
| Ex. 9 | P-3 | B-7 | D-1/D-3 | W-3 | S-1/S-2 |
| | (840) | (150) | (4/4) | | (18/6) |
| Ex. 10 | P-1 | B-8 | D-2/D-4 | W-2 | S-1/S-2 |
| | (810) | (180) | (4/4) | | (18/6) |
| Ex. 11 | P-4 | B-5/B-13 | D-1 | W-4 | S-1/S-3 |
| | (840) | (90/50) | (8) | | (18/6) |
| Ex. 12 | P-8a | B-5/B-7 | D-1 | W-5 | S-1/S-4 |
| | (840) | (75/75) | (8) | | (18/6) |
| Ex. 13 | P-1 | B-9 | D-1 | W-1 | S-1 |
| | (890) | (100) | (8) | | (24) |
| Ex. 14 | P-2 | B-10 | D-2 | W-2 | S-1/S-2 |
| | (850) | (140) | (8) | | (18/6) |
| Ex. 15 | P-8b | B-11 | D-1/D-3 | W-3 | S-1/S-2 |
| | (890) | (100) | (4/4) | | (18/6) |
| Ex. 16 | P-1 | B-12 | D-2/D-4 | W-2 | S-1/S-2 |
| | (890) | (100) | (4/4) | | (18/6) |
| Ex. 17 | P-4 | B-9/B-13 | D-1 | W-4 | S-1/S-3 |
| | (890) | (50/50) | (8) | | (18/6) |
| Ex. 18 | P-8b | B-9/B-11 | D-1 | W-5 | S-1/S-4 |
| | (890) | (50/50) | (8) | | (18/6) |
| Ex. 19 | P-1 | B-10 | D-1 | W-1 | S-1 |
| | (850) | (140) | (8) | | (24) |
| Ex. 20 | P-8b | B-10 | D-1 | W-2 | S-1/S-2 |
| | (890) | (100) | (8) | | (18/6) |
| Ex. 21 | P-4 | B-10 | D-1 | W-3 | S-1/S-2 |
| | (940) | (50) | (8) | | (18/6) |
| Ex. 22 | P-5 | B-10 | D-2 | W-2 | S-1/S-2 |
| | (790) | (200) | (8) | | (18/6) |
| Ex. 23 | P-6 | B-10 | D-3 | W-2 | S-1/S-2 |
| | (690) | (300) | (8) | | (18/6) |
| Ex. 24 | P-7 | B-10 | D-1 | W-3 | S-1/S-2 |
| | (840) | (150) | (8) | | (18/6) |
| Ex. 25 | P-9 | B-9 | D-1 | W-1 | S-1 |
| | (890) | (100) | (8) | | (24) |
| Ex. 26 | P-6 | B-13 | D-1 | W-3 | S-1/S-2 |
| | (890) | (100) | (8) | | (18/6) |
| Ex. 27 | P-1 | B-13 | D-1 | W-3 | S-1/S-2 |
| | (890) | (100) | (8) | | (18/6) |
| Ex. 28 | P-1 | B-14 | D-1 | W-3 | S-1/S-2 |
| | (890) | (100) | (8) | | (18/6) |

The brevity codes appearing in the table denote particular examples shown hereinbefore or have the following meaning.

### <Acid Generator>

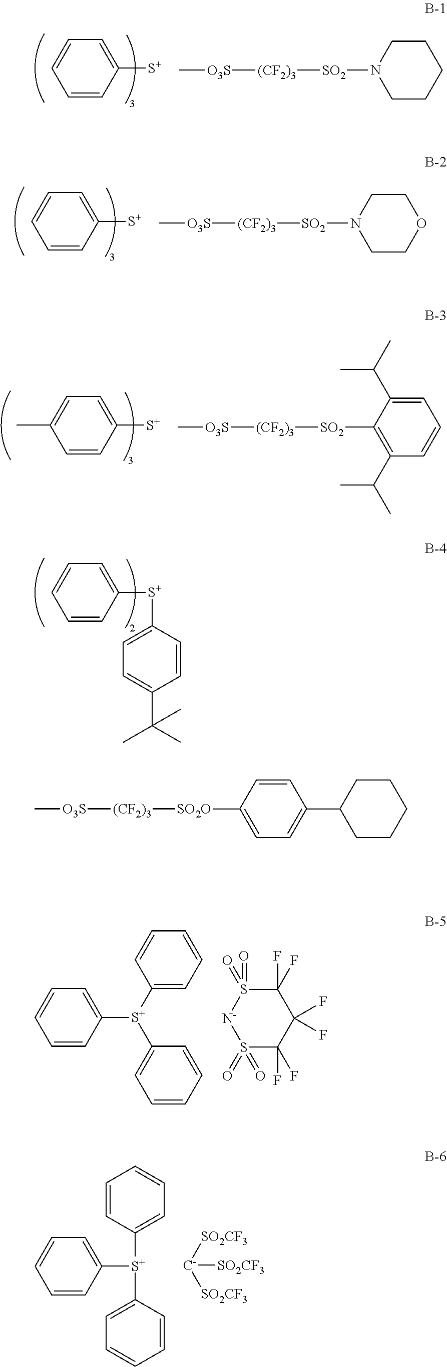

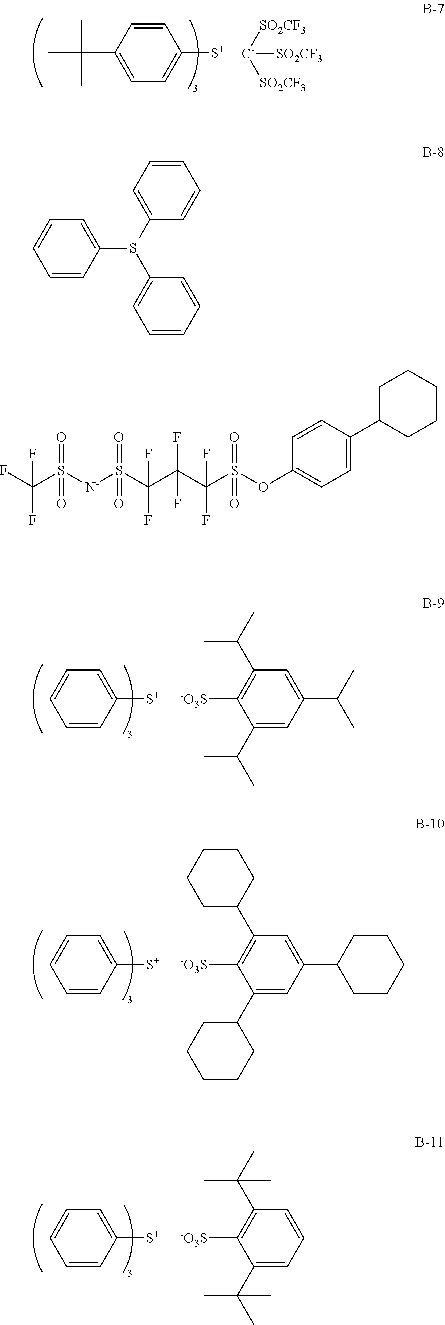

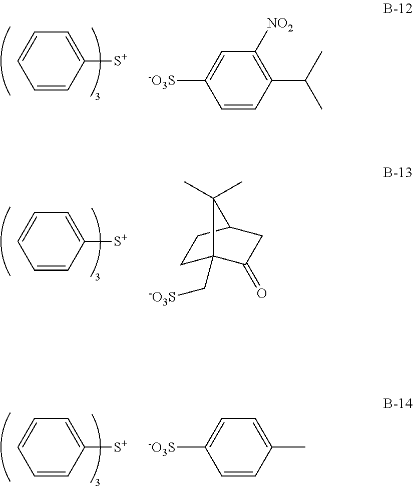

### <Organic Basic Compound>

D-1: tetra-(n-butyl)ammonium hydroxide,
D-2: 1,8-diazabicyclo[5.4.0]-7-undecene,
D-3: 2,4,5-triphenylimidazole, and
D-4: tridodecylamine.

### <Surfactant>

W-1: PF636 (produced by OMNOVA SOLUTIONS, INC.),
W-2: PF6320 (produced by OMNOVA SOLUTIONS, INC.),
W-3: PF656 (produced by OMNOVA SOLUTIONS, INC.),
W-4: PF6520 (produced by OMNOVA SOLUTIONS, INC.),
W-5: Megafac F176 (produced by Dainippon Ink & Chemicals, Inc.), and
W-6: Florad FC430 (produced by Sumitomo 3M Ltd.).

### <Coating Solvent>

S-1: propylene glycol monomethyl ether acetate (PGMEA),
S-2: propylene glycol monomethyl ether (PGME),
S-3: cyclohexanone, and
S-4: ethyl lactate.

TABLE 3
EB exposure

| | | | Sensitivity | Resolving | | | PED |
|---|---|---|---|---|---|---|---|
| | PAB* | PEB* | (E₀) | power | EL* | LWR | Stability |
| | (C. °/90 s) | (C. °/90 s) | (μC/cm²) | (nm) | (%) | (nm) | (nm/48 hr) |
| Ex. 1 | 120 | 120 | 25 | 50.0 | 40 | 3.5 | 1.5 |
| Ex. 2 | 120 | 120 | 30 | 50.0 | 40 | 3.5 | 1.5 |
| Ex. 3 | 120 | 120 | 30 | 50.0 | 45 | 4 | 1.5 |
| Ex. 4 | 120 | 120 | 30 | 50.0 | 40 | 3.5 | 1.5 |
| Ex. 5 | 120 | 120 | 28 | 50.0 | 40 | 4 | 2 |
| Ex. 6 | 120 | 120 | 25 | 50.0 | 40 | 3.5 | 1.5 |
| Ex. 26 | 120 | 120 | 40 | 100.0 | 15 | 15 | 6.5 |
| Ex. 27 | 120 | 120 | 35 | 62.5 | 20 | 7 | 5.5 |
| Ex. 7 | 120 | 120 | 25 | 50.0 | 40 | 3.5 | 1 |
| Ex. 8 | 120 | 120 | 30 | 50.0 | 40 | 3.5 | 1 |
| Ex. 9 | 120 | 120 | 30 | 50.0 | 45 | 4 | 1.2 |
| Ex. 10 | 120 | 120 | 30 | 50.0 | 40 | 3.5 | 1.5 |
| Ex. 11 | 120 | 120 | 28 | 50.0 | 40 | 4 | 1.5 |
| Ex. 12 | 120 | 120 | 25 | 50.0 | 40 | 3.5 | 1 |
| Ex. 26 | 120 | 120 | 40 | 100.0 | 15 | 15 | 6.5 |
| Ex. 27 | 120 | 120 | 35 | 62.5 | 20 | 7 | 5.5 |

| | | | | Resolving | Resolving | | | | Isolated |
|---|---|---|---|---|---|---|---|---|---|
| | | | Sensitivity | power | power | | | Bridge | space |
| | PAB* | PEB* | (E₀) | (dence) | (isolated) | EL* | LWR | margin | resolvability |
| | (C. °/90 s) | (C. °/90 s) | (μC/cm²) | (nm) | (nm) | (%) | (nm) | (%) | (nm) |
| Ex. 13 | 120 | 120 | 30 | 50.0 | 50.0 | 50 | 4 | 20 | 70 |
| Ex. 14 | 120 | 120 | 30 | 50.0 | 50.0 | 60 | 4.5 | 50 | 40 |
| Ex. 15 | 120 | 120 | 30 | 50.0 | 50.0 | 55 | 4 | 40 | 58 |
| Ex. 16 | 120 | 120 | 30 | 55.0 | 60.0 | 35 | 5 | 21 | 70 |
| Ex. 17 | 120 | 120 | 30 | 50.0 | 50.0 | 45 | 4.5 | 23 | 70 |
| Ex. 18 | 120 | 120 | 30 | 50.0 | 50.0 | 50 | 4.5 | 18 | 70 |
| Ex. 19 | 120 | 120 | 30 | 50.0 | 50.0 | 50 | 4 | 55 | 50 |
| Ex. 20 | 120 | 120 | 30 | 50.0 | 50.0 | 45 | 4.5 | 52 | 45 |
| Ex. 21 | 120 | 120 | 30 | 50.0 | 50.0 | 50 | 4 | 50 | 50 |
| Ex. 22 | 120 | 120 | 30 | 55.0 | 55.0 | 45 | 4 | 46 | 45 |
| Ex. 23 | 120 | 120 | 30 | 50.0 | 62.5 | 30 | 4.5 | 48 | 50 |
| Ex. 24 | 120 | 120 | 35 | 50.0 | 55.0 | 50 | 4 | 45 | 45 |
| Ex. 25 | 120 | 120 | 40 | 50.0 | 62.5 | 30 | 4.5 | 10 | 70 |
| Ex. 26 | 120 | 120 | 40 | 100.0 | 62.5 | 15 | 15 | 17 | 75 |
| Ex. 28 | 120 | 120 | 30 | 100.0 | 100.0 | 10 | 4.5 | 13 | 70 |

*PAB: Post-appln. bake, PEB: Post-exposure bake, EL: Exposure latitude

### (3) KrF Exposure Evaluation

### (3-1) Preparation of Resist Coating Liquid and Application Thereof

The coating liquid compositions with formulations given in Table 4 were prepared, and precision filtration thereof was performed using a membrane filter of 0.1 μm pore size, thereby obtaining resist solutions.

Each of the obtained resist solutions was applied onto an 8-inch Si wafer provided with a subcoating of DUV42 (60 nm) by means of a spin coater Mark 8 manufactured by Tokyo Electron Limited, and dried by baking on a hot plate set at the temperature indicated in Table 5. Thus, resist films each having a thickness of 0.25 μm were obtained.

### (3-2) Exposure

Each of the resist films obtained in the step (3-1) above was patternwise exposed by means of a KrF scanner (PAS5500/850, manufactured by ASML) under the exposure conditions of NA=0.80, annular illumination and σ=0.89/0.59.

The exposed resist film was baked on a hot plate set at the temperature indicated in Table 5.

The baked resist film was dipped in a 2.38 mass % aqueous tetramethylammonium hydroxide (TMAH) solution for 60 seconds, rinsed with water for 30 seconds and dried.

The thus obtained patterns were evaluated by the following methods. The evaluation results are given in Table 5 below.

### (3-3-1) Sensitivity (E₀)

Each of the obtained patterns was observed by means of a scanning electron microscope (model S-9220, manufactured by Hitachi, Ltd.). The sensitivity (E₀) was defined as the exposure amount at which 0.12 μm (line:space=1:1) was resolved.

### (3-3-2) Exposure Latitude

The exposure latitude was defined as the numeric value calculated by the following formula in which E₁ represented the sensitivity at which the pattern size was 0.108 μm and E₂ represented the sensitivity at which the pattern size was 0.132 μm.

Exposure latitude=(E₁−E₂)/E₀×100(%)

### (3-3-3) Line Width Roughness (LWR)

The line width was measured at arbitrary 30 points in a 50 μm region along the longitudinal direction of a 0.12 μm line pattern at the exposure amount exhibiting the above sensitivity. The data spread was evaluated by 3σ.

### (3-3-4) Bridge Margin

The exposure amount E₀ (optimum exposure amount) for resolving the obtained 0.12 μm line-and-space resist pattern was determined using a scanning electron microscope (model S-9260, manufactured by Hitachi, Ltd.). Further, the exposure amount E₁ for bridging occurring when the exposure amount was reduced from the exposure amount E₀ was determined. These exposure amounts were introduced in formula 1 below, and the index of bridge margin was defined as the thus calculated numeric value.

Bridge margin (%)=[(E₀−E₁)/E₀]×100 (1)

The larger the thus calculated value, the more favorable the bridge margin performance.

### (3-3-5) Isolated Space Resolvability

Each 150 nm isolated space pattern was observed through a scanning electron microscope (model S-9260, manufactured by Hitachi, Ltd.). The isolated space resolvability was defined as the minimum space width that can be resolved.

TABLE 4

| | | | Organic | | |
|---|---|---|---|---|---|
| | (A) | (B) Acid | basic | | |
| | Resin | generator | compound | Surfactant | Solvent |
| | (mg) | (mg) | (mg) | (2.5 mg) | (g) |
| Ex. 29 | P-1 | B-1 | D-1 | W-1 | S-1 |
| | (840) | (150) | (8) | | (14) |
| Ex. 30 | P-2 | B-2 | D-2 | W-2 | S-1/S-2 |
| | (840) | (150) | (8) | | (10.5/3.5) |
| Ex. 31 | P-3 | B-3 | D-1/D-3 | W-3 | S-1/S-2 |
| | (840) | (150) | (4/4) | | (10.5/3.5) |
| Ex. 32 | P-1 | B-4 | D-2/D-4 | W-2 | S-1/S-2 |
| | (840) | (150) | (4/4) | | (10.5/3.5) |
| Ex. 33 | P-4 | B-1/B-13 | D-1 | W-4 | S-1/S-3 |
| | (850) | (90/50) | (8) | | (10.5/3.5) |
| Ex. 34 | P-3 | B-1/B-3 | D-1 | W-5 | S-1/S-4 |
| | (840) | (75/75) | (8) | | (10.5/3.5) |
| Ex. 35 | P-1 | B-5 | D-1 | W-1 | S-1 |
| | (890) | (100) | (8) | | (14) |
| Ex. 36 | P-2 | B-6 | D-2 | W-2 | S-1/S-2 |
| | (840) | (150) | (8) | | (10.5/3.5) |
| Ex. 37 | P-8a | B-7 | D-1/D-3 | W-3 | S-1/S-2 |
| | (840) | (150) | (4/4) | | (10.5/3.5) |
| Ex. 38 | P-1 | B-8 | D-2/D-4 | W-2 | S-1/S-2 |
| | (810) | (180) | (4/4) | | (10.5/3.5) |
| Ex. 39 | P-4 | B-5/B-13 | D-1 | W-4 | S-1/S-3 |
| | (840) | (90/50) | (8) | | (10.5/3.5) |
| Ex. 40 | P-8a | B-5/B-7 | D-1 | W-5 | S-1/S-4 |
| | (840) | (75/75) | (8) | | (10.5/3.5) |
| Ex. 41 | P-1 | B-9 | D-1 | W-1 | S-1 |
| | (890) | (100) | (8) | | (14) |
| Ex. 42 | P-2 | B-10 | D-2 | W-2 | S-1/S-2 |
| | (850) | (140) | (8) | | (10.5/3.5) |
| Ex. 43 | P-8b | B-11 | D-1/D-3 | W-3 | S-1/S-2 |
| | (890) | (100) | (4/4) | | (10.5/3.5) |
| Ex. 44 | P-1 | B-12 | D-2/D-4 | W-2 | S-1/S-2 |
| | (890) | (100) | (4/4) | | (10.5/3.5) |
| Ex. 45 | P-4 | B-9/B-13 | D-1 | W-4 | S-1/S-3 |
| | (890) | (50/50) | (8) | | (10.5/3.5) |
| Ex. 46 | P-8b | B-9/B-11 | D-1 | W-5 | S-1/S-4 |
| | (890) | (50/50) | (8) | | (10.5/3.5) |
| Ex. 47 | P-1 | B-10 | D-1 | W-1 | S-1 |
| | (850) | (140) | (8) | | (24) |
| Ex. 48 | P-8b | B-10 | D-1 | W-2 | S-1/S-2 |
| | (890) | (100) | (8) | | (18/6) |
| Ex. 49 | P-4 | B-10 | D-1 | W-3 | S-1/S-2 |
| | (940) | (50) | (8) | | (18/6) |
| Ex. 50 | P-5 | B-10 | D-2 | W-2 | S-1/S-2 |
| | (790) | (200) | (8) | | (18/6) |
| Ex. 51 | P-6 | B-10 | D-3 | W-2 | S-1/S-2 |
| | (690) | (300) | (8) | | (18/6) |
| Ex. 52 | P-7 | B-10 | D-1 | W-3 | S-1/S-2 |
| | (840) | (150) | (8) | | (18/6) |
| Ex. 53 | P-9 | B-9 | D-1 | W-1 | S-1 |
| | (890) | (100) | (8) | | (24) |

The brevity codes appearing in the table denote particular examples shown hereinbefore.

TABLE 5
KrF exposure

| | | | Sensitivity | | |
|---|---|---|---|---|---|
| | PAB* | PEB* | (E₀) | EL* | LWR |
| | (C. °/90 s) | (C. °/90 s) | (mJ/cm²) | (%) | (nm) |
| Ex. 29 | 120 | 120 | 12.5 | 20 | 4.5 |
| Ex. 30 | 120 | 120 | 15 | 20 | 5 |
| Ex. 31 | 120 | 120 | 15 | 22.5 | 5 |
| Ex. 32 | 120 | 120 | 15 | 20 | 4.5 |
| Ex. 33 | 120 | 120 | 14 | 20 | 4.5 |
| Ex. 34 | 120 | 120 | 12.5 | 20 | 5 |
| Ex. 35 | 120 | 120 | 12.5 | 20 | 4.5 |
| Ex. 36 | 120 | 120 | 15 | 20 | 4.5 |
| Ex. 37 | 120 | 120 | 15 | 22.5 | 5 |
| Ex. 38 | 120 | 120 | 15 | 20 | 4.5 |
| Ex. 39 | 120 | 120 | 14 | 20 | 5 |
| Ex. 40 | 120 | 120 | 12.5 | 20 | 4.5 |

| | | | | | | | Isolated |
|---|---|---|---|---|---|---|---|
| | | | | | | | space |
| | | PEB* | Sensitivity | | | Bridge | resolv- |
| | PAB* | (C. °/ | (E₀) | EL* | LWR | margin | ability |
| | (C. °/90 s) | 90 s) | (mJ/cm²) | (%) | (nm) | (%) | (nm) |
| Ex. 41 | 120 | 120 | 15 | 25 | 4.5 | 20 | 150 |
| Ex. 42 | 120 | 120 | 15 | 30 | 5 | 50 | 100 |
| Ex. 43 | 120 | 120 | 15 | 27.5 | 4.5 | 40 | 120 |
| Ex. 44 | 120 | 120 | 15 | 20 | 5.5 | 21 | 150 |
| Ex. 45 | 120 | 120 | 15 | 22.5 | 5 | 23 | 150 |
| Ex. 46 | 120 | 120 | 15 | 25 | 5.5 | 18 | 150 |
| Ex. 47 | 120 | 120 | 15 | 30 | 4.5 | 19 | 100 |
| Ex. 48 | 120 | 120 | 15 | 27.5 | 5 | 17 | 110 |
| Ex. 49 | 120 | 120 | 15 | 25 | 4.5 | 15 | 100 |
| Ex. 50 | 120 | 120 | 15 | 30 | 4.5 | 13 | 95 |
| Ex. 51 | 120 | 120 | 15 | 22.5 | 5 | 55 | 100 |
| Ex. 52 | 120 | 120 | 15 | 30 | 4.5 | 52 | 100 |
| Ex. 53 | 120 | 120 | 15 | 27.5 | 5 | 50 | 150 |

*PAB: Post-appln. bake, PEB: Post-exposure bake, EL: Exposure latitude

### (4) EUV Exposure Evaluation

### (4-1) Preparation of Resist Coating Liquid and Application Thereof

The coating liquid compositions given in Table 6 were prepared, and precision filtration thereof was performed using a membrane filter of 0.1 μm pore size, thereby obtaining resist solutions.

Each of the obtained resist solutions was applied onto a 6-inch Si wafer having undergone HMDS treatment by means of a spin coater Mark 8 manufactured by Tokyo Electron Limited, and dried by baking on a hot plate set at the temperature indicated in Table 7. Thus, resist films each having a thickness of 0.05 μm were obtained.

### (4-2) EUV Exposure

The surface exposure of each of the obtained resist films was carried out using EUV light (wavelength 13 nm) while changing the exposure amount by 0.5 mJ at a time within the range of 0 to 10.0 mJ.

The exposed film was baked on a hot plate set at the temperature indicated in Table 7.

The baked resist film was dipped in a 2.38 mass % aqueous tetramethylammonium hydroxide (TMAH) solution for 60 seconds, rinsed with water for 30 seconds and dried.

The thus obtained patterns were evaluated by the following methods. The evaluation results are given in Table 7 below.

### (4-3-1) Sensitivity (Eth)

The sensitivity (Eth) was defined as the exposure amount at which the thickness of the resist film after development became 50% of that before exposure.

### (4-3-2) Film Retention Ratio

The film retention ratio (%) was defined as the numeric value calculated by the following formula.

(film thickness after development in unexposed areas/film thickness before exposure)×100(%)

### (4-3-3) Surface Roughness (Ra)

The surface roughness Ra (defined in JIS B0601) of each resist film after development at the sensitivity Eth was observed through an atomic force microscope AFM (Dimension 3100, manufactured by Veeco Japan).

TABLE 6

| | | | Organic | | |
|---|---|---|---|---|---|
| | (A) | (B) Acid | basic | | |
| | Resin | generator | compound | Surfactant | Solvent |
| | (mg) | (mg) | (mg) | (2.5 mg) | (g) |
| Ex. 54 | P-1 | B-1 | D-1 | W-1 | S-1 |
| | (840) | (150) | (8) | | (49) |
| Ex. 55 | P-2 | B-2 | D-2 | W-2 | S-1/S-2 |
| | (840) | (150) | (8) | | (37/12) |
| Ex. 56 | P-3 | B-3 | D-1/D-3 | W-3 | S-1/S-2 |
| | (840) | (150) | (4/4) | | (37/12) |
| Ex. 57 | P-1 | B-4 | D-2/D-4 | W-2 | S-1/S-2 |
| | (840) | (150) | (4/4) | | (37/12) |
| Ex. 58 | P-4 | B-1/B-13 | D-1 | W-4 | S-1/S-3 |
| | (850) | (90/50) | (8) | | (37/12) |
| Ex. 59 | P-3 | B-1/B-3 | D-1 | W-5 | S-1/S-4 |
| | (840) | (75/75) | (8) | | (37/12) |
| Ex. 60 | P-1 | B-5 | D-1 | W-1 | S-1 |
| | (890) | (100) | (8) | | (49) |
| Ex. 61 | P-2 | B-6 | D-2 | W-2 | S-1/S-2 |
| | (840) | (150) | (8) | | (37/12) |
| Ex. 62 | P-8a | B-7 | D-1/D-3 | W-3 | S-1/S-2 |
| | (840) | (150) | (4/4) | | (37/12) |
| Ex. 63 | P-1 | B-8 | D-2/D-4 | W-2 | S-1/S-2 |
| | (810) | (180) | (4/4) | | (37/12) |
| Ex. 64 | P-4 | B-5/B-13 | D-1 | W-4 | S-1/S-3 |
| | (840) | (90/50) | (8) | | (37/12) |
| Ex. 65 | P-8a | B-5/B-7 | D-1 | W-5 | S-1/S-4 |
| | (840) | (75/75) | (8) | | (37/12) |
| Ex. 66 | P-1 | B-9 | D-1 | W-1 | S-1 |
| | (890) | (100) | (8) | | (49) |
| Ex. 67 | P-2 | B-10 | D-2 | W-2 | S-1/S-2 |
| | (850) | (140) | (8) | | (37/12) |
| Ex. 68 | P-8b | B-11 | D-1/D-3 | W-3 | S-1/S-2 |
| | (890) | (100) | (4/4) | | (37/12) |
| Ex. 69 | P-1 | B-12 | D-2/D-4 | W-2 | S-1/S-2 |
| | (890) | (100) | (4/4) | | (37/12) |
| Ex. 70 | P-4 | B-9/B-13 | D-1 | W-4 | S-1/S-3 |
| | (890) | (50/50) | (8) | | (37/12) |
| Ex. 71 | P-8b | B-9/B-11 | D-1 | W-5 | S-1/S-4 |
| | (890) | (140) | (8) | | (37/12) |
| Ex. 72 | P-1 | B-10 | D-1 | W-1 | S-1 |
| | (850) | (140) | (8) | | (24) |
| Ex. 73 | P-8b | B-10 | D-1 | W-2 | S-1/S-2 |
| | (890) | (100) | (8) | | (18/6) |
| Ex. 74 | P-4 | B-10 | D-1 | W-3 | S-1/S-2 |
| | (940) | (50) | (8) | | (18/6) |
| Ex. 75 | P-5 | B-10 | D-2 | W-2 | S-1/S-2 |
| | (790) | (200) | (8) | | (18/6) |
| Ex. 76 | P-6 | B-10 | D-3 | W-2 | S-1/S-2 |
| | (690) | (300) | (8) | | (18/6) |
| Ex. 77 | P-7 | B-10 | D-1 | W-3 | S-1/S-2 |
| | (840) | (150) | (8) | | (18/6) |
| Ex. 78 | P-9 | B-9 | D-1 | W-1 | S-1 |
| | (890) | (100) | (8) | | (24) |

The brevity codes appearing in the table denote particular examples shown hereinbefore.

TABLE 7
EUV exposure

| | | | Sensitivity | Film |
|---|---|---|---|---|
| | PAB* | PEB* | (Eth) | retention |
| | (C. °/90 s) | (C. °/90 s) | (mJ/cm²) | ratio (%) |
| Ex. 54 | 120 | 120 | 2.8 | 95.0 |
| Ex. 55 | 120 | 120 | 3.3 | 98.0 |
| Ex. 56 | 120 | 120 | 3.3 | 97.0 |
| Ex. 57 | 120 | 120 | 3.3 | 96.0 |
| Ex. 58 | 120 | 120 | 3.1 | 95.0 |
| Ex. 59 | 120 | 120 | 2.8 | 98.0 |
| Ex. 60 | 120 | 120 | 8.3 | 98.0 |
| Ex. 61 | 120 | 120 | 10.0 | 98.0 |
| Ex. 62 | 120 | 120 | 10.0 | 98.5 |
| Ex. 63 | 120 | 120 | 10.0 | 97.5 |
| Ex. 64 | 120 | 120 | 9.3 | 97.5 |
| Ex. 65 | 120 | 120 | 8.3 | 98.0 |

| | | | Sensitivity | Film | Surface |
|---|---|---|---|---|---|
| | PAB* | PEB* | (Eth) | Retention | Roughness |
| | (C. °/90 s) | (C. °/90 s) | (mJ/cm²) | ratio (%) | (Ra) (nm) |
| Ex. 66 | 120 | 120 | 10 | 98.0 | 10.5 |
| Ex. 67 | 120 | 120 | 9.5 | 98.0 | 4.5 |
| Ex. 68 | 120 | 120 | 10 | 97.0 | 6.5 |
| Ex. 69 | 120 | 120 | 10.5 | 96.0 | 13 |
| Ex. 70 | 120 | 120 | 10 | 97.0 | 14 |
| Ex. 71 | 120 | 120 | 9.5 | 98.0 | 13 |
| Ex. 72 | 120 | 120 | 10 | 98.0 | 5 |
| Ex. 73 | 120 | 120 | 9.5 | 98.0 | 4.5 |
| Ex. 74 | 120 | 120 | 10 | 97.0 | 6 |
| Ex. 75 | 120 | 120 | 10.5 | 96.0 | 5 |
| Ex. 76 | 120 | 120 | 10 | 97.0 | 5.5 |
| Ex. 77 | 120 | 120 | 10 | 97.0 | 5 |
| Ex. 78 | 120 | 120 | 10.5 | 96.0 | 11.5 |

*PAB: Post-appln. bake, PEB: Post-exposure bake, EL: Exposure latitude

It is apparent from Table 3, Table 5 and Table 7 that the patterns obtained by the patterning method using the resist compositions of the present invention exhibit favorable performances.

1. An actinic-ray- or radiation-sensitive resin composition comprising a resin (A) whose solubility in an alkali developer is increased by the action of an acid, the resin containing any of the units of general formula (AI) below and any of the units of general formula (AII) below, and a compound (B) that when exposed to actinic rays or radiation, generates an acid with any of the structures of general formula (BI) below, 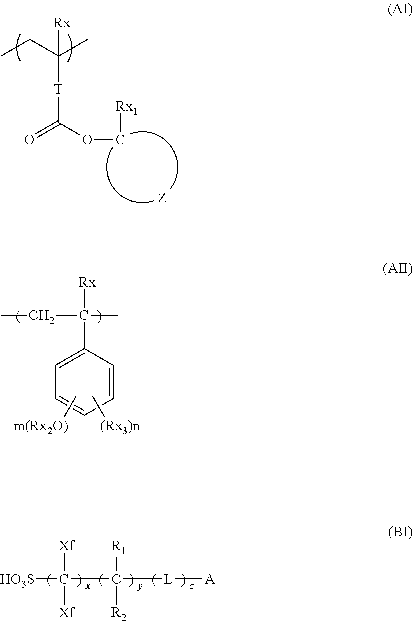
in general formula (AI),
Rx represents a hydrogen atom, a methyl group, a trifluoromethyl group or a hydroxymethyl group;
T represents a single bond or a bivalent connecting group;
Rx₁ represents a linear or branched alkyl group or a monocycloalkyl group; and
Z cooperates with C to thereby form a monocycloalkyl group having 5 to 8 carbon atoms,
in general formula (AII),
Rx represents a hydrogen atom, a methyl group, a trifluoromethyl group or a hydroxymethyl group;
Rx₂ represents a hydrogen atom or an organic group;
Rx₃ represents a non-acid-decomposable group; and
m is an integer of 1 to 4 and n is an integer of 0 to 4, provided that 1≦n+m≦5, and provided that when m is 2 to 4, the plurality of Rx₂s may be identical to or different from each other and when n is 2 to 4, the plurality of Rx₃s may be identical to or different from each other, and
in general formula (BI),
each of Xfs independently represents a fluorine atom or an alkyl group substituted with at least one fluorine atom;
each of R₁ and R₂ independently represents a group selected from among a hydrogen atom, a fluorine atom, an alkyl group and an alkyl group substituted with at least one fluorine atom, provided that R₁s, and also R₂s, may be identical to or different from each other;
L represents a single bond or a bivalent connecting group, provided that Ls may be identical to or different from each other;
A represents a group with a cyclic structure; and
x is an integer of 1 to 20, y an integer of 0 to 10 and z an integer of 0 to 10.

2. The actinic-ray- or radiation-sensitive resin composition according to claim 1, wherein at least one Xf is a fluorine atom in general formula (BI).

3. An actinic-ray- or radiation-sensitive resin composition comprising a resin (A) whose solubility in an alkali developer is increased by the action of an acid, the resin containing any of the units of general formula (AI) below and any of the units of general formula (AII) below, and a compound (B) that when exposed to actinic rays or radiation, generates an acid with any of the structures of general formulae (BII) and (BIII) below, 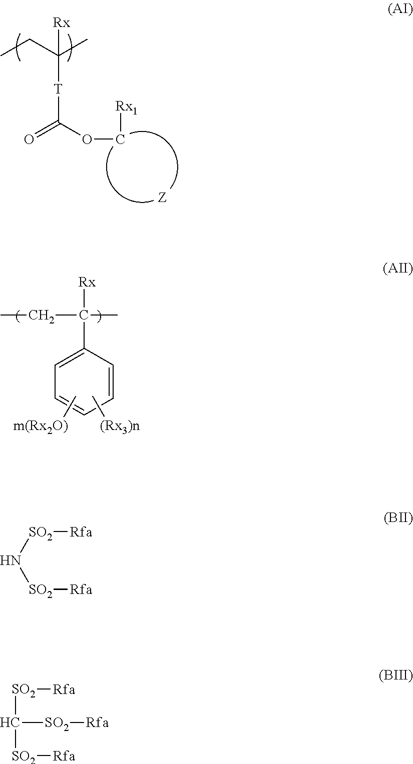
in general formula (AI),
Rx represents a hydrogen atom, a methyl group, a trifluoromethyl group or a hydroxymethyl group;
T represents a single bond or a bivalent connecting group;
Rx₁ represents a linear or branched alkyl group or a monocycloalkyl group; and
Z cooperates with C to thereby form a monocycloalkyl group having 5 to 8 carbon atoms,
in general formula (AII),
Rx represents a hydrogen atom, a methyl group, a trifluoromethyl group or a hydroxymethyl group;
Rx₂ represents a hydrogen atom or an organic group;
Rx₃ represents a non-acid-decomposable group; and
m is an integer of 1 to 4 and n is an integer of 0 to 4, provided that 1≦n+m≦5, and provided that when m is 2 to 4, the plurality of Rx₂s may be identical to or different from each other and when n is 2 to 4, the plurality of Rx₃s may be identical to or different from each other, and
in general formulae (BII) and (BIII),
each of Rfas independently represents a monovalent organic group containing a fluorine atom, provided that the plurality of Rfas may be bonded to each other to thereby form a ring.

4. An actinic-ray- or radiation-sensitive resin composition comprising a resin (A) whose solubility in an alkali developer is increased by the action of an acid, the resin containing any of the units of general formula (AI) below and any of the units of general formula (AII) below, and a compound (B) that when exposed to actinic rays or radiation, generates an acid with any of the structures of general formula (BIV) below, 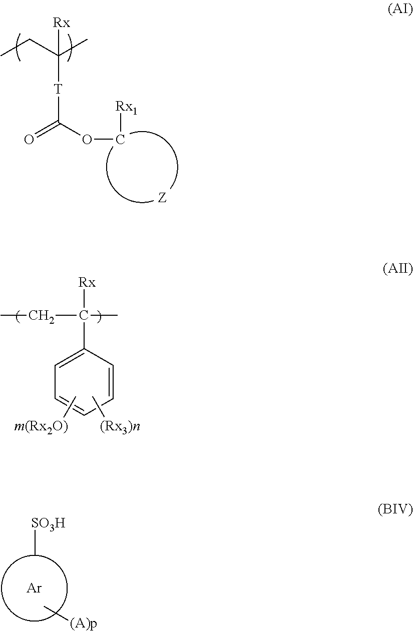
in general formula (AI),
Rx represents a hydrogen atom, a methyl group, a trifluoromethyl group or a hydroxymethyl group;
T represents a single bond or a bivalent connecting group;
Rx₁ represents a linear or branched alkyl group or a monocycloalkyl group; and
Z cooperates with C to thereby form a monocycloalkyl group having 5 to 8 carbon atoms,
in general formula (AII),
Rx represents a hydrogen atom, a methyl group, a trifluoromethyl group or a hydroxymethyl group;
Rx₂ represents a hydrogen atom or an organic group;
Rx₃ represents a non-acid-decomposable group; and
m is an integer of 1 to 4 and n is an integer of 0 to 4, provided that 1≦n+m≦5, and provided that when m is 2 to 4, the plurality of Rx₂s may be identical to or different from each other and when n is 2 to 4, the plurality of Rx₃s may be identical to or different from each other, and
in general formula (BIV),
Ar represents an aromatic ring in which a further substituent other than the A-groups may be introduced;
p is an integer of 1 or greater; and
A represents a group containing a hydrocarbon group having 3 or more carbon atoms, provided that when p is 2 or greater, the plurality of A-groups may be identical to or different from each other.

5. The actinic-ray- or radiation-sensitive resin composition according to claim 4, wherein general formula (BIV), A represents a group containing a hydrocarbon group having 4 or more carbon atoms.

6. The actinic-ray- or radiation-sensitive resin composition according to claim 4, wherein general formula (BIV), A represents a group containing a cyclohydrocarbon group having 4 or more carbon atoms.

7. The actinic-ray- or radiation-sensitive resin composition according to claim 4, wherein general formula (BIV), A represents a group containing a cyclohexyl group.

8. The actinic-ray- or radiation-sensitive resin composition according to claim 4, wherein in general formula (BIV), Ar is a benzene ring and p is an integer of 2 or greater, provided that among the two or more A-groups, two A-groups are placed on the ortho positions to the group —SO₃H and that the carbon atom of each of the A-groups adjacent to Ar is a tertiary or quaternary carbon atom.

9. The actinic-ray- or radiation-sensitive resin composition according to claim 4, wherein in general formula (BIV), as the further substituent other than the A-groups, at least one substituent selected from among a group containing a hydrocarbon group having 1 or more carbon atoms, a halogen atom, a hydroxyl group, a carboxyl group, a cyano group and a nitro group is introduced in the group represented by Ar.

10. The actinic-ray- or radiation-sensitive resin composition according to claim 1, wherein the units of general formula (AI) have the structures of general formula (AI-1) below, 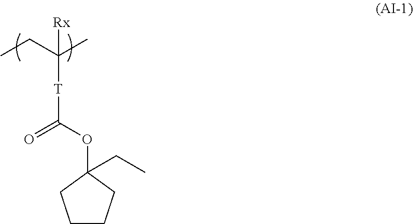
in general formula (AI-1), Rx and T are as defined above in general formula (AI).

11. The actinic-ray- or radiation-sensitive resin composition according to claim 3, wherein the units of general formula (AI) have the structures of general formula (AI-1) below, 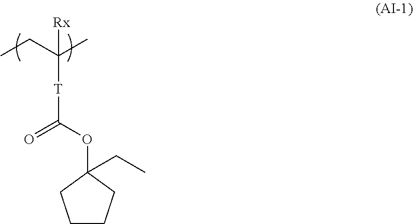
in general formula (AI-1), Rx and T are as defined above in general formula (AI).

12. The actinic-ray- or radiation-sensitive resin composition according to claim 4, wherein the units of general formula (AI) have the structures of general formula (AI-1) below, 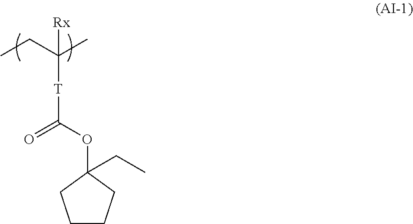
in general formula (AI-1), Rx and T are as defined above in general formula (AI).

13. A method of forming a pattern, comprising forming the actinic-ray- or radiation-sensitive resin composition according to claim 1 into a film, exposing the film and developing the exposed film.

14. A method of forming a pattern, comprising forming the actinic-ray- or radiation-sensitive resin composition according to claim 3 into a film, exposing the film and developing the exposed film.

15. A method of forming a pattern, comprising forming the actinic-ray- or radiation-sensitive resin composition according to claim 4 into a film, exposing the film and developing the exposed film.

16. The method of forming a pattern according to claim 13, wherein electron beams, X-rays or EUV light is used as an exposure light source.

17. The method of forming a pattern according to claim 14, wherein electron beams, X-rays or EUV light is used as an exposure light source.

18. The method of forming a pattern according to claim 15, wherein electron beams, X-rays or EUV light is used as an exposure light source.
